(19) United States
(12) Patent Application Publication
(10) Pub. No.: US 2025/0040283 A1
(43) Pub. Date: Jan. 30, 2025

(54) LIGHT DETECTION DEVICE AND ELECTRONIC DEVICE

(71) Applicant: SONY SEMICONDUCTOR SOLUTIONS CORPORATION, KANAGAWA (JP)

(72) Inventors: MACHIKO KAMETANI, KANAGAWA (JP); MANABU TOMITA, KANAGAWA (JP); HIROFUMI YAMASHITA, KANAGAWA (JP); KEIJI NISHIDA, KANAGAWA (JP); RYOHEI TAKAYANAGI, KANAGAWA (JP); SHINICHI MIYAKE, KANAGAWA (JP); HIDETOSHI OISHI, KANAGAWA (JP); AKITO SHIMIZU, KANAGAWA (JP); TAKANORI OKAMURA, KANAGAWA (JP)

(21) Appl. No.: 18/715,762

(22) PCT Filed: Dec. 1, 2022
(86) PCT No.: PCT/JP2022/044455

§ 371 Date: Jun. 3, 2024

(30) Foreign Application Priority Data
Dec. 9, 2021 (JP) 2021-200252

(51) Int. Cl. H01L 27/146

(52) U.S. Cl. CPC H01L 27/14636; H01L 27/14616; H01L 27/14634; H01L 27/14645

(57) ABSTRACT

Provided is a light detection device which allows influence on adjacent pixels to be reduced. The light detection device includes a first substrate portion, a second substrate portion, and a through via. The first substrate portion has a pixel configured to photoelectrically convert incident light. The second substrate portion has a readout circuit configured to output a pixel signal based on charge output from the pixel to a signal line. The through via configured to connect the first substrate portion and the second substrate portion. The pixel has a floating diffusion configured to temporarily retain charge generated by photoelectric conversion. The readout circuit has a first pixel transistor connected to the floating diffusion through the through via and a second pixel transistor connected to the first pixel transistor and the signal line. The through via is provided, in plan view, in a direction orthogonal to a wiring path configured to connect between a contact portion of the first pixel transistor and a contact portion of the second pixel transistor in a region of the pixel.

### TECHNICAL FIELD

The present technology (technology according to the present disclosure) relates to a light detection device and an electronic device including the light detection device.

### BACKGROUND ART

With the advent of microfabrication process and improvement in mounting density, the area per pixel in imaging devices with a two-dimensional structure has been reduced. In recent years, imaging devices with a three-dimensional structure have been developed to achieve further downsizing of imaging devices and higher pixel density (see for example PTL 1). The imaging device with a three-dimensional structure includes a semiconductor substrate having a plurality of sensor pixels thereon and a semiconductor substrate having a signal processing circuit thereon to process signals obtained from the sensor pixels, and these semiconductor substrates are stacked on each other. Note that the sensor pixel includes a photodiode as a photoelectric conversion unit and a plurality of pixel transistors.

### CITATION LIST

### Patent Literature

### [PTL 1]

WO 2020/262559

### SUMMARY

### Technical Problem

The imaging device with a two-dimensional structure has no vias for connecting the layered substrates, which allows for flexibility in designing, and the influence on adjacent diffusion layers is negligible. However, in imaging devices with a three-dimensional structure, mutual influence with adjacent pixels cannot be ignored as pixels become finer and more stacked.

The stacked arrangement of pixels makes it difficult to design the structure in consideration of the position of vias that connect two semiconductor substrates. When pixel transistors are shared among a plurality of sensor pixels, for example 2×2 pixels, an amplification transistor and a selection transistor as pixel transistors should be in series, and FD (floating diffusion) wirings are laid out to minimize the distance between the FD wirings, the FD wirings are closer to the vertical signal line (VSL) of an adjacent pixel, the capacitance with the adjacent vertical signal line increases.

With the foregoing in view, it is an object of the present disclosure to provide a light detection device and an electronic device that allow the influence on adjacent pixels to be reduced.

### Solution to Problem

A light detection device according to one aspect of the present disclosure includes a first substrate portion having a pixel configured to photoelectrically convert incident light, a second substrate portion stacked on a surface of the first substrate portion opposite to a surface on which the light is incident and having a readout circuit configured to output a pixel signal based on charge output from the pixel to a signal line, and a through-via configured to connect the first substrate portion and the second substrate portion, the pixel has a floating diffusion configured to temporarily retain charge generated by photoelectric conversion, the readout circuit has a first pixel transistor connected to the floating diffusion through the through-via and a second pixel transistor connected to the first pixel transistor and the signal line, and the through-via is provided, in plan view, between a contact portion provided at a gate electrode of the first pixel transistor and a contact portion provided at a gate electrode of the second pixel transistor in a region of the pixel and in a position shifted in a second direction orthogonal to a first direction in which the contact portion of the first pixel transistor and the contact portion of the second pixel transistor are provided.

An electronic device according to another aspect of the present disclosure includes a light detection device, the light detection device includes a first substrate portion having a pixel configured to photoelectrically convert incident light, a second substrate portion stacked on a surface of the first substrate portion opposite to a surface on which the light is incident and having a readout circuit configured to output a pixel signal based on charge output from the pixel to a signal line, and a through-via configured to connect the first substrate portion and the second substrate portion, the pixel has a floating diffusion configured to temporarily retain charge generated by photoelectric conversion, the readout circuit has a first pixel transistor connected to the floating diffusion through the through-via and a second pixel transistor connected to the first pixel transistor and the signal line, and the through-via is provided, in plan view, between a contact portion provided at a gate electrode of the first pixel transistor and a contact portion provided at a gate electrode of the second pixel transistor in a region of the pixel and in a position shifted in a second direction orthogonal to a first direction in which the contact portion of the first pixel transistor and the contact portion of the second pixel transistor are provided.

### BRIEF DESCRIPTION OF DRAWINGS

FIG. 1 is a schematic plan layout of an exemplary configuration of a light detection device according to a first embodiment of the present disclosure.

FIG. 2 is a block diagram of the exemplary configuration of the light detection device according to the first embodiment of the present disclosure.

FIG. 3 is an equivalent circuit diagram of a pixel unit in the light detection device according to the first embodiment of the present disclosure.

FIG. 4 is a schematic plan view of an essential part of the exemplary configuration of the pixel unit in the light detection device according to the first embodiment of the present disclosure.

FIG. 5A is a schematic cross-sectional view of a cross-sectional structure taken along line A4-A4 in FIG. 4.

FIG. 5B is a schematic cross-sectional view of a cross-sectional structure taken along line B4-B4 in FIG. 4.

FIG. 6 is a plan view of a readout circuit including an amplification transistor, a selection transistor, a reset transistor, and a switching transistor in a pixel in a comparative example.

FIG. 7 is a diagram for illustrating an example of how a through-via in an FD wiring is arranged close to a vertical signal line of an adjacent pixel in a comparative example.

FIG. 8A is a plan view (1) of an exemplary arrangement of a through via according to the first embodiment of the present disclosure.

FIG. 8B is a plan view (2) of an exemplary arrangement of a through-via according to the first embodiment of the present disclosure.

FIG. 8C is a plan view (3) of an exemplary arrangement of a through-via according to the first embodiment of the present disclosure.

FIG. 8D is a plan view (4) of an exemplary arrangement of a through-via according to the first embodiment of the present disclosure.

FIG. 9A is a plan view (5) of an exemplary arrangement of a through-via according to the first embodiment of the present disclosure.

FIG. 9B is a plan view (6) of an exemplary arrangement of a through-via according to the first embodiment of the present disclosure.

FIG. 9C is a plan view (7) of an exemplary arrangement of a through via according to the first embodiment of the present disclosure.

FIG. 9D is a plan view (8) of an exemplary arrangement of a through-via according to the first embodiment of the present disclosure.

FIG. 10 is a plan view of a readout circuit in a 2×2 shared pixel in a light detection device according to a second embodiment of the present disclosure.

FIG. 11 is a plan view of a readout circuit in a 2×2 shared pixel in a light detection device according to a modification of the second embodiment of the present disclosure.

FIG. 12A is a diagram of an exemplary configuration of a MOS transistor according to a third embodiment of the present disclosure.

FIG. 12B is a diagram of an exemplary configuration of the MOS transistor according to the third embodiment of the present disclosure.

FIG. 12C is a diagram of an exemplary configuration of the MOS transistor according to the third embodiment of the present disclosure.

FIG. 13 is a plan view of an exemplary configuration of a MOS transistor according to a fourth embodiment of the present disclosure.

FIG. 14 is a cross-sectional view taken along line II-II in FIG. 13.

FIG. 15 is a block diagram of an exemplary functional configuration of a light detection device according to a fifth embodiment of the present disclosure.

FIG. 16 is a schematic plan view of a general configuration of the light detection device shown in FIG. 15.

FIG. 17 is a schematic cross sectional view taken along line III-III′ shown in FIG. 16.

FIG. 18 is a schematic cross-sectional view of an example of a specific configuration of the light detection device shown in FIG. 17.

FIG. 19 is a block diagram of an exemplary configuration of an electronic device to which the present technology is applied.

FIG. 20 illustrates a general configuration of an endoscopic surgery system.

FIG. 21 is a block diagram of an exemplary functional configuration of a camera head and a CCU.

FIG. 22 is a block diagram of an example of a general configuration of a vehicle control system.

FIG. 23 is a view for illustrating an example of installation positions of an vehicle exterior information detection unit and an imaging unit.

### DESCRIPTION OF EMBODIMENTS

Embodiments of the present disclosure will be described below with reference to the drawings. In descriptions of the drawings referred to in the following description, the same or similar portions will be denoted by the same or similar reference signs and redundant descriptions will be omitted. However, it should be noted that the drawings are schematic in nature and the relationships between thicknesses and planar dimensions, ratios of thicknesses of respective devices or respective members differ from reality. Therefore, specific thicknesses and dimensions should be determined by considering the following descriptions. In addition, it goes without saying that the drawings also include portions having different dimensional relationships and ratios from each other.

In addition, it is to be understood that definitions of directions such as upward and downward in the following description are merely definitions provided for the sake of brevity and are not intended to limit technical ideas of the present disclosure. For example, it is obvious that when an object is observed after being rotated by 90 degrees, up down is converted into and interpreted as left-right, and when an object is observed after being rotated by 180 degrees, up-down is interpreted as being inverted.

In the following embodiment, in the three directions orthogonal to each other in a space, a first direction and a second direction orthogonal to each other in the same plane are set to an X direction and a Y direction, respectively, and a third direction orthogonal to each of the first direction and the second direction is defined as a Z direction.

The advantageous effects described in the present specification are merely exemplary and are not restrictive, and other advantageous effects may be produced.

### First Embodiment

In this first embodiment, an example in which the present technology is applied to a light detection device that is a rear-face emission type complementary metal oxide semiconductor (CMOS) image sensor will be described.

### (Overall Configuration of Light Detection Device)

The overall configuration of the light detection device 1A will be described to start with.

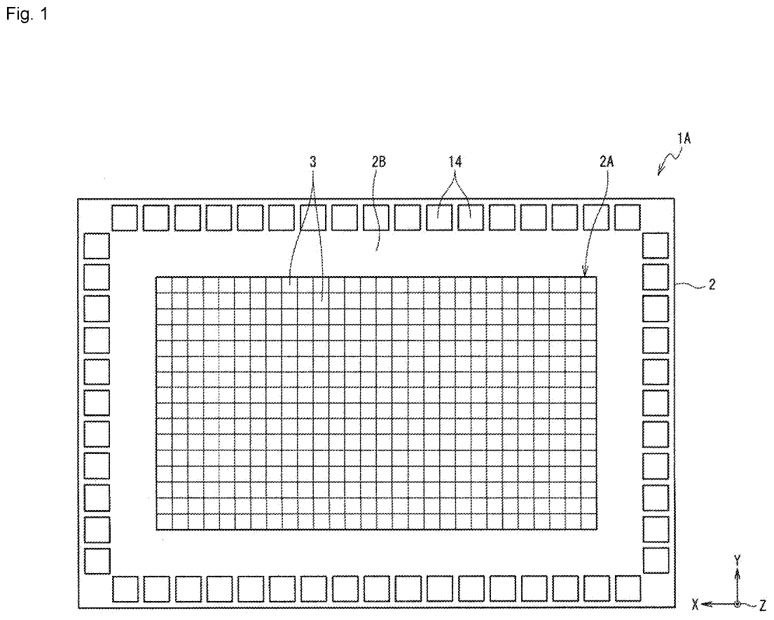

As shown in FIG. 1, the light detection device 1A according to the first embodiment of the present disclosure includes, as a main element, a semiconductor chip 2 having a rectangular two-dimensional plan shape in plan view. In other words, the light detection device 1A is mounted on the semiconductor chip 2. The light detection device 1A takes in image light from an object through an optical lens (not shown) and converts the light quantity of incident light that forms an image on an imaging surface into an electrical signal on a pixel basis and outputs the signal as a pixel signal.

As shown in FIG. 1, the semiconductor chip 2 on which the light detection device 1A is mounted has a pixel region 2A in a rectangular shape provided in a center part and a peripheral region 2B provided outside of the pixel region 2A to surround the pixel region 2A on a two-dimensional plane including an X direction and a Y direction intersecting with each other.

The pixel region 2A is a light receiving surface that receives light collected for example by an optical system. In the pixel region 2A, a plurality of pixels 3 are arranged in a matrix of rows and columns in a two-dimensional plane including the X and Y directions. Stated differently, the pixels 3 are repeatedly arranged in the X and Y directions which are orthogonal to each other within the two-dimensional plane.

As illustrated in FIG. 1, a plurality of bonding pads 14 are disposed in the peripheral region 2B. Each of the plurality of bonding pads 14, for example, is disposed along one side among four sides in the two-dimensional plane of the semiconductor chip 2. Each of the plurality of bonding pads 14 is an input/output terminal used when the semiconductor chip 2 is electrically connected to an external device.

### <Logic Circuit>

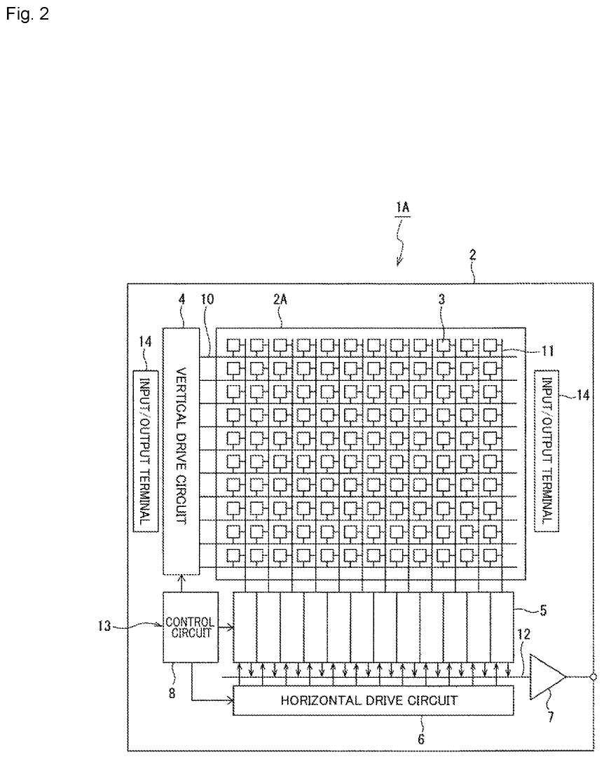

As shown in FIG. 2, the semiconductor chip 2 includes a logic circuit 13 that includes a vertical drive circuit 4, a column signal processing circuit 5, a horizontal drive circuit 6, an output circuit 7, and a control circuit 8. The logic circuit 13 externally outputs output voltage (Vout) for each of the pixels 3. The logic circuit 13 includes for example a CMOS (Complementary MOS) circuit including, as field effect transistors, a p-channel conductivity type (first conductivity type) metal oxide semiconductor field effect transistor (MOSFET) and an n-channel conductivity type (second conductivity type) MOSFET.

For example, the vertical drive circuit 4 includes a shift register. The vertical drive circuit 4 sequentially selects a desired pixel drive line 10, supplies a pulse for driving the pixels 3 to the selected pixel drive line 10, and drives respective pixels 3 in unit of rows. In other words, the vertical drive circuit 4 sequentially performs selective scanning of the pixels 3 of the pixel region 2A in units of rows in a vertical direction and supplies a pixel signal from the pixel 3 based on signal electric charge generated in accordance with a received light quantity by the photoelectric conversion element of each pixel 3 to the column signal processing circuit 5 through a vertical signal line 11.

For example, the column signal processing circuit 5 is provided for each of the columns of pixels 3 to perform signal processing such as noise removal to signals output from a row of pixels 3 on a pixel column basis. For example, the column signal processing circuit 5 performs signal processing such as correlated double sampling (CDS) for removing pixel-specific fixed pattern noise and analog-digital (AD) conversion.

For example, the horizontal drive circuit 6 is constituted of a shift register. The horizontal drive circuit 6 sequentially selects each column signal processing circuit 5 by sequentially outputting a horizontal scanning pulse to the column signal processing circuit 5 and outputs a pixel signal on which signal processing has been performed from each column signal processing circuit 5 to the horizontal signal line 12.

The output circuit 7 performs signal processing on the pixel signals sequentially supplied from the respective column signal processing circuits 5 through the horizontal signal line 12 and outputs resultant pixel signals. As the signal processing, for example, buffering, black level adjustment, a column deviation correction, various types of digital signal processing, and the like can be used.

The control circuit 8 generates a clock signal or a control signal as a reference for operations of the vertical drive circuit 4, the column signal processing circuit 5, the horizontal drive circuit 6, and the like on the basis of a vertical synchronization signal, a horizontal synchronization signal, and a master clock signal. In addition, the control circuit 8 outputs the generated clock signal or control signal to the vertical drive circuit 4, the column signal processing circuit 5, the horizontal drive circuit 6, and the like.

### <Pixel Unit>

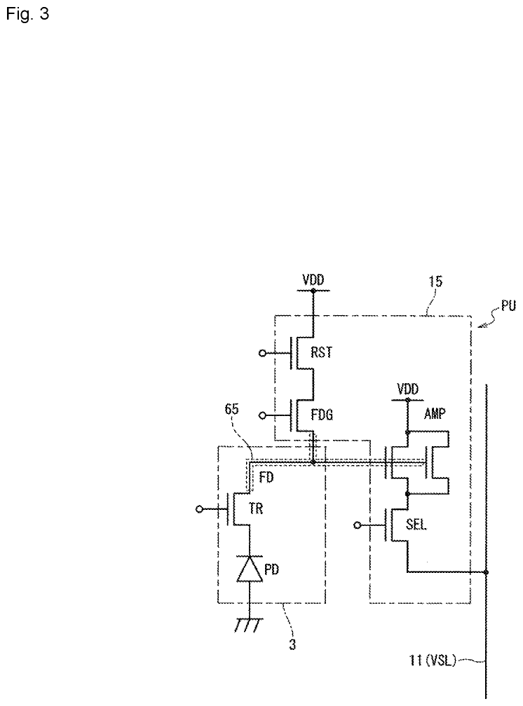

For example, the semiconductor chip 2 includes, though not limited, a pixel unit PU as shown in FIG. 3. The pixel unit PU includes one pixel 3 and a readout circuit 15 that reads out signal charge retained in the pixel 3 as shown in FIG. 3.

The pixel 3 includes a photoelectric conversion element PD, a transfer transistor TR, and a charge retention region FD (Floating Diffusion). The photoelectric conversion element PD generates signal charge according to a received light quantity. The transfer transistor TR transfers the signal charge photoelectrically converted by the photoelectric conversion element PD to the charge retention region FD. The charge retention region FD temporarily retains (stores) the signal charge transferred from the photoelectric conversion element PD via the transfer transistor TR. The transfer transistor TR may be a field-effect transistor such as a MOSFET with a silicon oxide (SiO2) film as the gate insulating film. The transfer transistor TR can also be a MISFET (Metal Insulator Semiconductor FET) that has a silicon nitride (Si3N4) film or a layered film such as a silicon nitride film and a silicon oxide film as the gate insulating film.

The photoelectric conversion element PD has its cathode side electrically connected to the source region of the transfer transistor TR, and the photoelectric conversion element PD has its anode side electrically connected to a reference potential line (e.g., a ground potential line). The photoelectric conversion element PD may be a photodiode. The drain region of the transfer transistor TR is also used as the charge retention region FD, and the transfer transistor TR has its gate electrode electrically connected to a transfer transistor drive line among the pixel drive lines 10 (see FIG. 2).

As shown in FIG. 3, the readout circuit 15 includes a plurality of pixel transistors, such as a switching transistor FDG, a reset transistor RST, an amplification transistor AMP, and a selection transistor SEL. These pixel transistors (FDG, RST, AMP, and SEL) are for example planar MOSFETs as field effect transistors. These pixel transistors may also be MISFETs.

The selection transistor SEL and the switching transistor FDG may be omitted if necessary.

The switching transistor FDG has its source region (the input end of the readout circuit 15) electrically connected to the charge retention region FD and its drain region electrically connected to the source region of the reset transistor RST and the gate electrode of the amplification transistor AMP. The switching transistor FDG has its gate electrode electrically connected to a switching transistor drive line among the pixel drive lines 10 shown in FIG. 2.

The reset transistor RST has its source region electrically connected to the drain region of the switching transistor FDG and its drain region electrically connected to the power supply line VDD. The reset transistor RST has its gate electrode electrically connected to a reset transistor drive line among the pixel drive lines 10 shown in FIG. 2.

The amplification transistor AMP has its source region electrically connected to the drain region of the selection transistor SEL and its drain region electrically connected to the power supply line VDD. The amplification transistor AMP has its gate electrode electrically connected to the source region of the switching transistor FDG and the charge retention region FD.

The selection transistor SEL has its source region electrically connected to the vertical signal line 11 and its drain region electrically connected to the source region of the amplification transistor AMP. The selection transistor SEL has its gate electrode electrically connected to a selection transistor drive line among the pixel drive lines 10 shown in FIG. 2.

Note that when the selection transistor SEL is omitted, the amplification transistor AMP has its source region electrically connected to the vertical signal line 11 (VSL). When the switching transistor FDG is omitted, the reset transistor RST has its source region electrically connected to the gate electrode of the amplification transistor AMP and the charge retention region FD.

When turned on, the transfer transistor TR transfers signal charge generated in the photoelectric conversion element PD to the charge retention region FD. When turned on, the reset transistor RST resets the potential (signal charge) of the charge retention region FD to the potential of the power supply line VDD. The selection transistor SEL controls timing for outputting a pixel signal from the readout circuit 15.

The amplification transistor AMP generates, as a pixel signal, a signal at voltage corresponding to the level of the signal charge retained in the charge retention region FD. The amplification transistor AMP constitutes a source follower type amplifier and is configured to output a pixel signal at voltage corresponding to the level of the signal charge generated by the photoelectric conversion element PD. When the selection transistor SEL is turned on, the amplification transistor AMP amplifies the potential of the charge retention region FD and outputs a pixel signal corresponding to the potential to the column signal processing circuit 5 via the vertical signal line 11 (VSL).

The switching transistor FDG controls the charge retention by the charge retention region FD and adjusts the voltage multiplication factor according to the potential amplified by the amplification transistor AMP.

During the operation of the light detection device 1A according to the first embodiment, signal charge generated by the photoelectric conversion element PD of the pixel 3 is retained (stored) in the charge retention region FD via the transfer transistor TR of the pixel 3. The signal charge retained in the charge retention region FD is then read out by the readout circuit 15 and applied to the gate electrode of the amplification transistor AMP of the readout circuit 15. The gate electrode of the selection transistor SEL of the readout circuit 15 is provided with a control signal for selection on a horizontal line from the vertical shift register. By setting the control signal for selection to a high (H) level, the selection transistor SEL conducts, and current corresponding to the potential of the charge retention region FD, which has been amplified by the amplification transistor AMP, is passed to the vertical signal line 11. Also, by setting, to a high (H) level, the control signal for reset to be applied to the gate electrode of the reset transistor RST of the readout circuit 15, the reset transistor RST conducts, and the signal charge stored in the charge retention region FD is reset.

### (Specific Configuration of Light Detection Device)

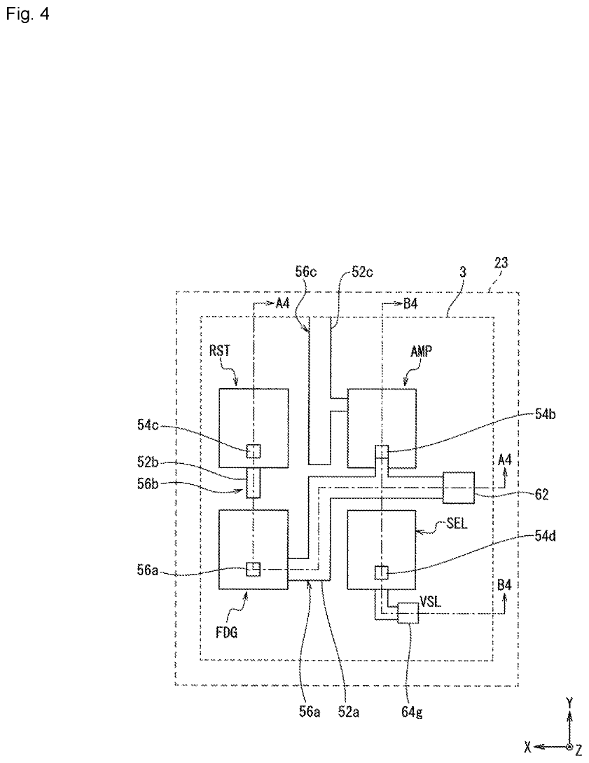

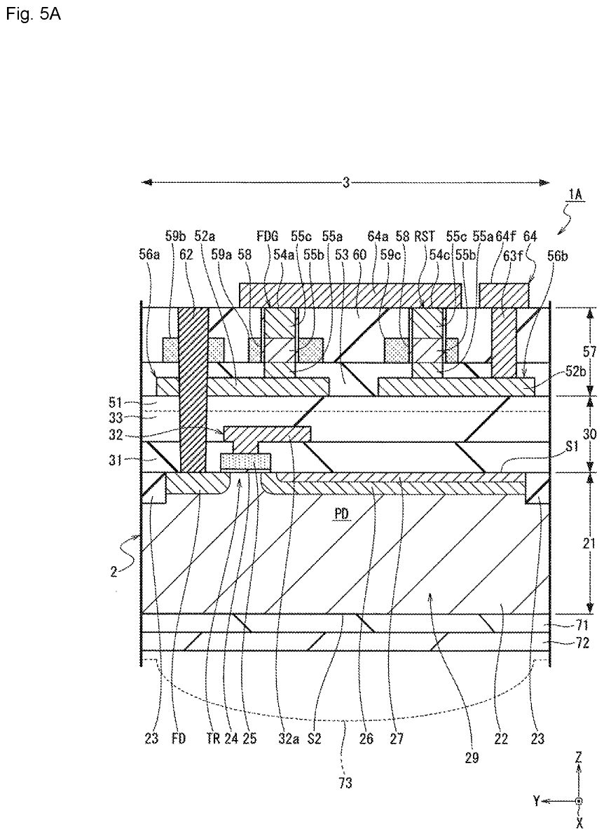

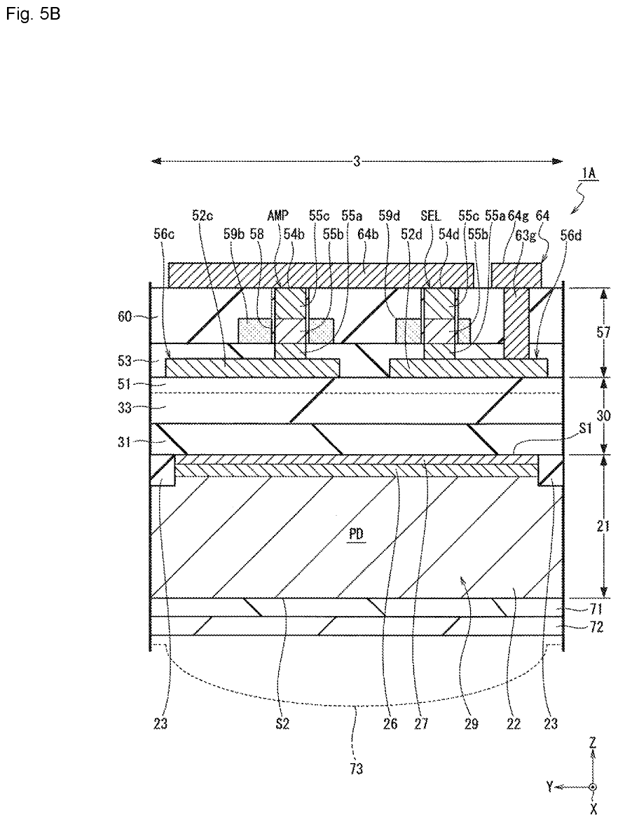

Next, a specific configuration of the semiconductor chip 2 (light detection device 1A) will be described with reference to FIGS. 4, 5A, and 5B. FIG. 4 is a plan view of the readout circuit 15 including the amplification transistor AMP, the selection transistor SEL, the reset transistor RST, and the switching transistor FDG in the pixel 3. FIG. 5A is a partial longitudinal cross sectional view of an exemplary sectional structure of the semiconductor chip 2 taken along the dotted dash line A4-A4 in FIG. 4. FIG. 5B is a partial longitudinal cross-sectional view of an exemplary sectional structure of the semiconductor chip 2 taken along the dotted dash line B4-B4 in FIG. 4. Note that in FIGS. 4, 5A, and 5B, the top and bottom are inverted with respect to FIG. 1 for ease of viewing, and the layer above a wiring layer 64 which will be described is not shown.

### (Semiconductor Chip)

As shown in FIGS. 5A and 5B, the semiconductor chip 2 includes a semiconductor substrate 21 for example formed from single crystal silicon as a first substrate portion and an insulating layer 30 provided on the side of a first surface S1 of the first surface S1 and a second surface S2 located on opposite sides to each other of the semiconductor substrate 21 in the thickness-wise direction (Z-direction) of the semiconductor substrate 21. The semiconductor chip 2 further includes a semiconductor layer 57 provided, as a second substrate portion, on the side of the first surface S1 opposite to the side of the first surface S1 of the semiconductor substrate 21 through the insulating layer 30. The semiconductor chip 2 further includes an insulating film 53, an insulating film 60, and the wiring layer 64 provided through the insulating layer 30 on the side of the first surface S1 of the semiconductor substrate 21. In other words, the light detection device 1A according to the first embodiment has a three-dimensional structure in which the semiconductor substrate 21 and the semiconductor layer 57 are stacked on each other through the insulating layer 30.

Here, the first surface S1 of the semiconductor substrate 21 may also be referred to as a main surface or an element formation surface, and the second surface S2 may also be referred to as a back surface or a light incident surface. According to the first embodiment, light to be photoelectrically converted by the photoelectric conversion element PD is incident from the side of the second surface S2 of the semiconductor substrate 21, and therefore the second surface S2 of the semiconductor substrate 21 may also be referred to as a light incident surface.

As shown in FIGS. 5A and 5B, the semiconductor chip 2 further includes a planarization film 71, a color filter 72, and a microlens 73, which are stacked on the side of second surface S2 side (light incident surface side) of the semiconductor substrate 21, in order from the side of second surface S2. The planarization film 71 planarizes the side of the second surface S2 (light incident surface side) of the semiconductor substrate 21. The microlens 73 focuses incident light onto the semiconductor substrate 21. The color filter 72 performs color-separation on incident light onto the semiconductor substrate 21. The color filter 72 and the microlens 73 are provided for each of the pixels 3.

### (Photoelectric Conversion Unit and Isolation Region)

As shown in FIGS. 5A and 5B, a photoelectric conversion unit 29 is provided for each of the pixels 3 on the semiconductor substrate 21. The photoelectric conversion unit 29 is partitioned by isolation regions 23 provided on the side of the first surface S1 of the semiconductor substrate 21. The isolation region 23 has, without limitation, an STI (Shallow Trench Isolation) structure for example having an isolation trench formed on the surface layer on the side of the first surface S1 of the semiconductor substrate 21 and an isolation insulating film selectively embedded within the isolation trench. The isolation region 23 is arranged between the photoelectric conversion units 29 adjacent to each other in a two-dimensional plane and isolates the side of the first surface S1 of the semiconductor substrate 21 for each of the pixels 3.

Here, the isolation region 23 corresponding to one photoelectric conversion unit 29 (one pixel 3) has a rectangular ringed planar pattern (ring-shaped planar pattern) in plan view, as shown in FIG. 4. Although not shown, the isolation region 23 corresponding to the entire pixel region 2A has a composite planar pattern having a lattice planar pattern in which isolation regions 23 extending in the X direction and the isolation region 23 extending in the Y direction intersect in a rectangular ringed planar pattern which surrounds the pixel region 2A in plan view.

### (Photoelectric Conversion Element, Transfer Transistor, and Charge Retention Region)

As shown in FIGS. 5A and 5B, the photoelectric conversion units 29 each include the photoelectric conversion element PD, the transfer transistor TR, and the charge retention region FD as described above.

### (Photoelectric Conversion Element)

The photoelectric conversion element PD includes a p-type (first conductivity type) well region (semiconductor region) 22 provided in the photoelectric conversion unit 29, an n-type (second conductivity type) semiconductor region 26 provided on the surface layer of the well region 22 to form a pn junction with the well region 22, a p-type semiconductor region 27 provided on the surface layer of the semiconductor region 26 to form a pn junction with the semiconductor region 26.

### (Transfer Transistor)

As shown in FIG. 5A, the transfer transistor TR includes a gate insulating film 24 provided on the side of the first surface S1 of the semiconductor substrate 21, a gate electrode 25 provided through the gate insulating film 24 on the side of the first surface S1 of the semiconductor substrate 21, the p-type well region 22 that serves as a channel formation region where a channel is to be formed. The transfer transistor TR also includes the n-type semiconductor region 26 that serves as a source region and the charge retention region FD that serves as a drain region. The n-type semiconductor region 26 is for example formed aligned with the gate electrode 25.

The gate insulating film 24 may be a silicon oxide film. The gate electrode 25 may be an impurity-implanted polycrystalline silicon film to reduce resistance.

### (Charge Retention Region)

The charge retention region FD includes an n-type semiconductor region formed in alignment with the gate electrode 25 on the surface layer on the side of the first surface S1 of the semiconductor substrate 21.

### (Insulating Layer)

As shown in FIGS. 5A and 5B, the insulating layer 30 includes an insulating film 31 provided on the side of the first surface S1 of the semiconductor substrate 21 to cover the gate electrode 25, a wiring layer 32 provided on the insulating film 31, an insulating film 33 provided on the insulating film 31 to cover the wiring layer 32, and an insulating film 51 bonded to the insulating film 33 on the side of the insulating film 33 opposite to the semiconductor substrate 21. The wiring layer 32 is provided with a plurality of wirings. FIG. 5A illustrates a wiring 32a electrically connected to the gate electrode 25 through an aperture in the insulating film 31. The insulating film 31 may include one of a silicon oxide (SiO) film, a silicon nitride (SiN) film, a silicon oxynitride (SiON) film, and a silicon carbonitride (SiCN) film, or a laminated film including two or more of the above. The insulating films 33 and 51 may be silicon oxide films. The wirings including the wiring 32a of the wiring layer 32 may be a metal film such as copper (Cu) or a Cu-based alloy.

### (Second Semiconductor Layer)

As shown in FIGS. 5A and 5B, the semiconductor layer 57 is provided on the insulating layer 30 on the opposite side to the semiconductor substrate 21. As shown in FIGS. 4, 5A, and 5B, the semiconductor layer 57 includes a first active region 56a, a second active region 56b, and a third active region 56d, which are isolated from each other on the insulating layer 30. These first to third active regions 56a, 56b, and 56d are provided for each of the pixels 3.

Here, in FIGS. 5A and 5B, the first active region 56a is shown in FIG. 5A, the second active region 56b is shown in FIGS. 5A and 5B, and the third active region 56d is shown in FIG. 5B.

As shown in FIGS. 4 and 5A, the first active region 56a has an island-shaped base 52a and a contact portion 54a that protrudes upward from the base 52a in the thickness-wise direction (Z direction) of the base 52a.

As shown in FIGS. 4, 5A, and 5B, the second active region 56b has an island-shaped base 52b and contact portions 54b (see FIG. 5B) and 54c (see FIG. 5A) that protrude upward from the base 52b in the thickness-wise direction (Z direction) of the base 52b.

As shown in FIGS. 4 and 5B, the third active region 56d has an island-shaped base 52d and a contact portion 54d that protrudes upward from the base 52d in the thickness-wise direction (Z direction) of the base 52d.

The bases 52a, 52b, and 52d are each formed for example by reducing the thickness of the semiconductor substrate and then patterning the semiconductor substrate into a prescribed shape. The bases 52a, 52b and 52d are provided flush on the surface of the insulating layer 30.

As shown in FIGS. 5A and 5B, the contact portions 54a, 54b, 54c and 54d each include an n-type first semiconductor portion 55a, a low concentration semiconductor or i-type (intrinsic semiconductor, non-doped) second semiconductor portion 55b, and an n-type third semiconductor portion 55c stacked sequentially from the respective bases (52a, 52b, 52d) side. The contact portions 54a, 54b, 54c and 54d are each formed by selective epitaxial growth of the n-type first semiconductor portion 55a through an opening provided for each of the bases (52a, 52b, 52d) in the insulating film 53 covering the bases (52a, 52b, and 52d), followed by selective epitaxial growth of the i-type second semiconductor portion 55b and then the n-type third semiconductor portion 55c on the n-type first semiconductor portion 55a. The respective parts of the first semiconductor portion 55a have conductivity of the same type as the corresponding bases 52a, 52b, and 52d and are electrically connected with the bases 52a, 52b, 52d. The second semiconductor portion 55b may have p-type conductivity.

In each of the contact portions 54a, 54b, 54c and 54d, the n-type first and third semiconductor portions 55a and 55c function as a pair of main electrode regions that are source and drain regions of the pixel transistor, and the n-type second semiconductor portion 55b functions as a channel formation region of the pixel transistor.

Each of the bases (52a, 52b, 52d) and each of the contact portions (54a, 54b, 54c, 54d) is for example made of monocrystalline silicon (single crystal silicon). Each of the contact portions 54a, 54b, 54c and 54d may have a cylindrical shape, but may also have a prismatic shape.

As shown in FIGS. 5A and 5B, the first to third active regions 56a, 56b and 56c are covered with an insulating film 53 except for the contact portions (54a, 54b and 54d). The insulating film 60 is provided on the insulating film 53. The insulating film 60 covers the gate electrodes (59a, 59b, 59c, and 59d) on the insulating film 53 and surrounds the contact portions (54a, 54b, and 54d). The insulating films 53 and 60 may include one of a silicon oxide (SiO2) film, a silicon nitride (Si3N4) film, a silicon oxynitride (SiON) film, and a silicon carbonitride (SiCN) film, or may be a laminated film including at least two of the above stacked on each other.

### (Switching Transistor)

As shown in FIGS. 4 and 5A, the switching transistor FDG includes a second semiconductor portion 55b provided in the contact portion 54a of the first active region 56a to function as a channel formation region where a channel is to be formed, a gate electrode 59a provided outside the second semiconductor portion 55b through a gate insulating film 58. The switching transistor FDG further includes a pair of main electrode regions that function as a source region and a drain region. One of the pair of main electrode regions includes the base 52a and the first semiconductor portion 55a provided in the contact portion 54a and may function as a source region. The other of the pair of main electrode regions includes the third semiconductor portion 55c provided in the contact portion 54a and may function as a drain region. In other words, the switching transistor FDG has a vertical structure in which the pair of main electrode regions (the base 52a and the first semiconductor portion 55a and the third semiconductor portion 55c) is provided in the first active region 56a with the channel formation region (the second semiconductor portion 55b) therebetween and parted in the protruding direction of the contact portion 54a. The gate electrode 59a is provided to surround the second semiconductor portion 55b in the contact portion 54a in plan view.

### (Amplification Transistor)

As shown in FIGS. 4 and 5B, the amplification transistor AMP includes the second semiconductor portion 55b provided in the contact portion 54b of the second active region 56b to function as a channel formation region where a channel is to be formed, the gate electrode 59b provided outside the second semiconductor portion 55b through the gate insulating film 58. The amplification transistor AMP further includes a pair of main electrode regions that function as a source region and a drain region. One of the pair of main electrode regions includes the third semiconductor portion 55c provided in the contact portion 54b and may function as a source region.

### (Reset Transistor)

As shown in FIGS. 4 and 5A, the reset transistor RST includes the second semiconductor portion 55b provided in the contact portion 54c of the second active region 56b to function as a channel formation region where a channel is to be formed, the gate electrode 59c provided outside the second semiconductor portion 55b through the gate insulating film 58. The reset transistor RST further includes a pair of main electrode regions that function as a source region and a drain region. One of the pair of main electrode regions includes the third semiconductor portion 55c provided in the contact portion 54c and may function as a source region. The other of the pair of main electrode regions includes the base 52b and the first semiconductor portion 55a provided in the contact portion 54c and may function as a drain region. In other words, the reset transistor RST has a vertical structure in which the pair of main electrode regions (the third semiconductor portion 55c, the base 52b, and the first semiconductor portion 55a) is provided in the second active region 56b with the channel formation region (the second semiconductor portion 55b) therebetween and isolated in the projection direction of the contact portion 54c. The gate electrode 59c is provided to surround the second semiconductor portion 55b of the contact portion 54c in plan view.

### (Selection Transistor)

As shown in FIGS. 4 and 5B, the selection transistor SEL includes the second semiconductor portion 55b provided in the contact portion 54d of the third active region 56d to as a channel formation region where a channel is to be formed, the gate electrode 59d provided outside the second semiconductor portion 55b through gate insulating film 58. The selection transistor SEL further includes a pair of main electrode regions that function as a source region and a drain region. One of the pair of main electrode regions includes the base 52d and the first semiconductor portion 55a provided on the contact portion 54d and may function for example as a source region. The other of the pair of main electrode regions includes the third semiconductor portion 55c provided in the contact portion 54d to function for example as a drain region. In other words, the selection transistor SEL has a vertical structure in which the pair of main electrode regions (the base 52d and the first semiconductor portion 55a, and the third semiconductor portion 55c) are provided in the third active region 56d with the channel formation region (the second semiconductor portion 55b) therebetween and isolated in the protruding direction of the contact portion 54d. The gate electrode 59d is provided to surround the second semiconductor portion 55b of the contact portion 54d in plan view.

The gate insulating film 58 includes, for example, a silicon oxide film. Each of the gate electrodes 59a, 59b, 59c and 59d is formed by the same process and includes, for example, a polycrystalline silicon film implanted with an impurity to reduce resistance. The gate insulating film 58 and the gate electrodes (59a, 59b, 59c, and 59d) can also be made of High K-Metal Gate.

### (Wiring Layer)

As shown in FIGS. 4, 5A and 5B, the wiring layer 64 is provided on the insulating film 60. The wiring layer 64 includes wirings 64a, 64b, 64e, 64f, and 64g. These wirings 64a, 64b, 64e, 64f, and 64g are covered with an insulating film provided on the insulating film 60, which is not shown for convenience.

As shown in FIGS. 4 and 5A, the third semiconductor portion 55c of the contact portion 54a is directly connected to one end side of the wiring 64a provided on the insulating film 60 and electrically connected with the wiring 64a. The third semiconductor portion 55c of the contact portion 54c is directly connected to the other end side of the wiring 64a and electrically connected with the wiring 64a. More specifically, the drain region of the switching transistor FDG (the third semiconductor portion 55c of the contact portion 54a) and the source region of the reset transistor RST (the third semiconductor portion 55c of the contact portion 54c) are electrically connected through the wiring 64a.

The wiring 64a is drawn so that one end side thereof overlaps the contact portion 54a of the first active region 56a and the other end side overlaps the contact portion 54c of the second active region 56b in plan view.

As shown in FIGS. 4 and 5B, the third semiconductor portion 55c of each of the two contact portions 54b is directly connected to one end side of the wiring 64b on the insulating film 60 and electrically connected with the wiring 64b. The third semiconductor portion 55c of the contact portion 54d is directly connected to the other end side of the wiring 64b and electrically connected with the wiring 64b.

More specifically, the source region of the amplification transistor AMP (the third semiconductor portion 55c of the contact portion 54b) and the drain region of the selection transistor SEL (the third semiconductor portion 55c of the contact portion 54d) are electrically connected through the wiring 64b.

The wiring 64b is drawn so that one end side thereof overlaps the contact portion 54b of the second active region 56b and the other end side overlaps the contact portion 54d of the third active region 56d in plan view. More specifically, the wiring 64b extends over the second active region 56b and the third active region 56d in the two-dimensional plane of the semiconductor chip 2.

As shown in FIGS. 4 and 5A, the base 52b of the second active region 56b is electrically connected to the wiring 64f on the insulating film 60 through the contact electrode (a conductive plug or a via wiring) 63f embedded in the insulating films 53 and 60. The wiring 64f is electrically connected to the power supply line VDD shown in FIG. 3, though not shown in detail. In other words, the drain region of the amplification transistor AMP and the source region of the reset transistor RST are electrically connected to the power supply line VDD.

As shown in FIGS. 4 and 5B, the base 52d of the third active region 56d is electrically connected to the wiring 64g on the insulating film 60 through the contact electrode (a conductive plug or a via wiring) 63g embedded in the insulating films 53 and 60. The wiring 64g is electrically connected to the vertical signal line 11 shown in FIG. 3, though not shown in detail.

### (Conductive Path)

As shown in FIGS. 4 and 5A, the semiconductor chip 2 further includes a through-via 62 extending in the Z direction across the semiconductor substrate 21 as the first semiconductor layer and the semiconductor layer 57 as the second semiconductor layer.

The through-via 62 is directly connected to the base 52a of the first active region 56a, which functions as a source region in one of the pair of main electrode regions of the switching transistor (first field effect transistor) FDG. The through-via 62 is also directly connected to the gate electrode 59b of the amplification transistor AMP and each of the charge retention regions FD of the semiconductor substrate 21. The through-via 62 is electrically connected with these bases 52a, the gate electrode 59b, and the charge retention regions FD. As shown in FIG. 3, the through-via 62 constitutes a conductive path 65 that electrically connects the source region of the switching transistor FDG (base 52a), the gate electrode (59b) of the amplification transistor AMP, and each of the charge retention regions FD.

According to the first embodiment, the gate electrode 59b of the amplification transistor AMP, the base 52a of the first active region 56a as the source region of the switching transistor FDG, and the charge retention region FD overlap each other in plan view. The through-via 62 extends linearly in the thickness-wise direction (Z direction) of the semiconductor substrate 21, penetrates the gate electrode 59b and the base 52a of the first active region 56a from the side of the insulating film 60 to reach the charge retention region FD and is directly connected with each of the gate electrode 59b, the base 52a, and the charge retention region FD.

Examples of high-melting point metal materials which can be used for the through-via 62 and the contact electrodes 63f and 63g described above include titanium (Ti), tungsten (W), cobalt (Co), and molybdenum (Mo), and tungsten (W) may be used.

### Comparative Example with Respect to Embodiment

Meanwhile, the stacked arrangement of the pixels makes it difficult to design the structure in consideration of the position of the through-via 62 that connects the semiconductor substrate on the first floor to the semiconductor substrate on the second floor.

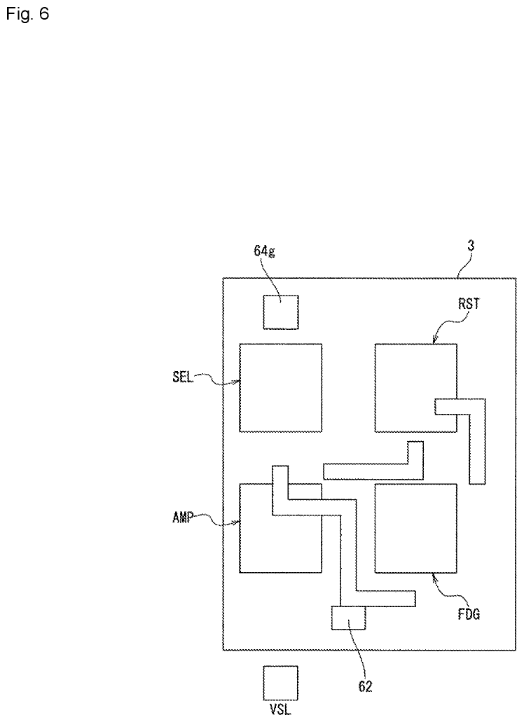

FIG. 6 is a plan view of the readout circuit 15 including the amplification transistor AMP, the selection transistor SEL, the reset transistor RST, and the switching transistor FDG in a pixel 3 in a comparative example. In FIG. 6, the same parts as those in FIG. 4 are designated by the same reference characters, and detailed descriptions thereof will not be provided.

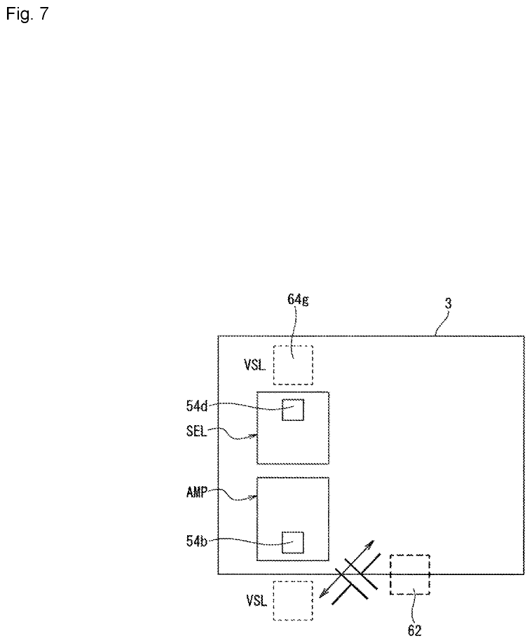

In the comparative example, in an attempt to minimize the distance between FD wirings, as shown in FIG. 7, the through-via 62 of the FD wiring is closer to the vertical signal line (VSL) 11 of another adjacent pixel 3, resulting in a larger capacitance with the adjacent vertical signal line (VSL) 11.

### Solution According to First Embodiment

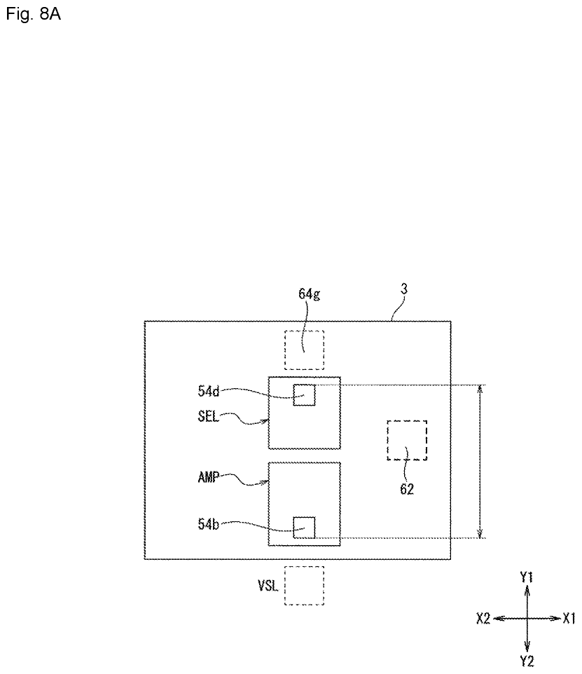

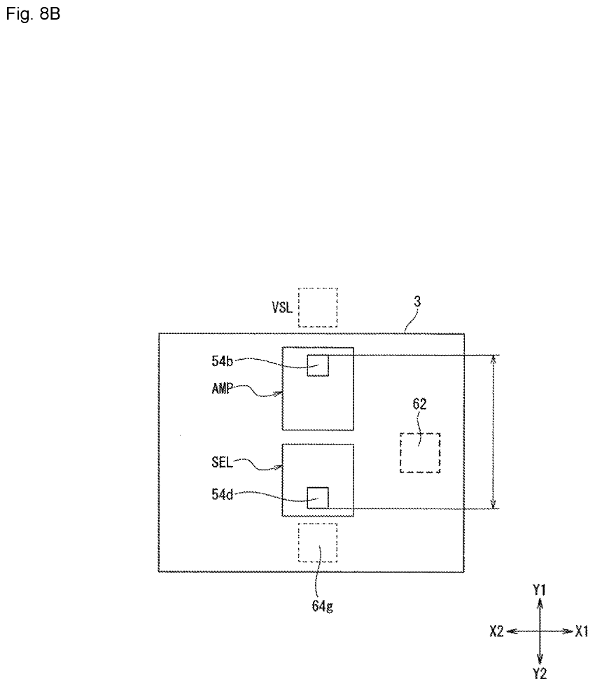

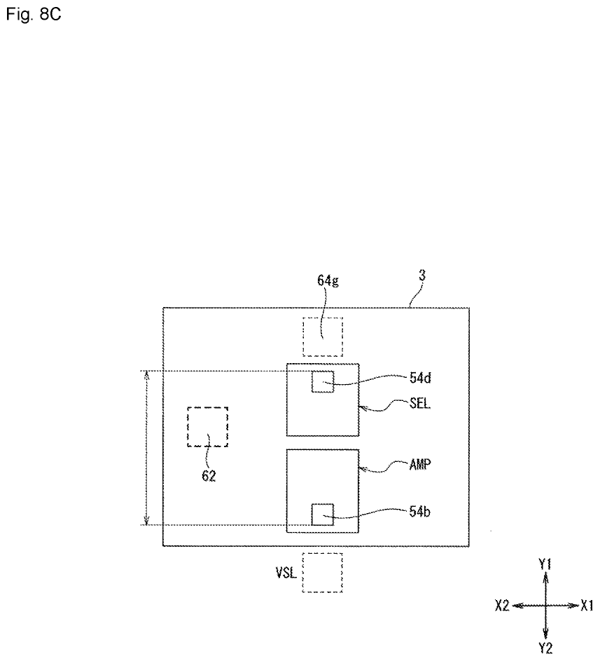

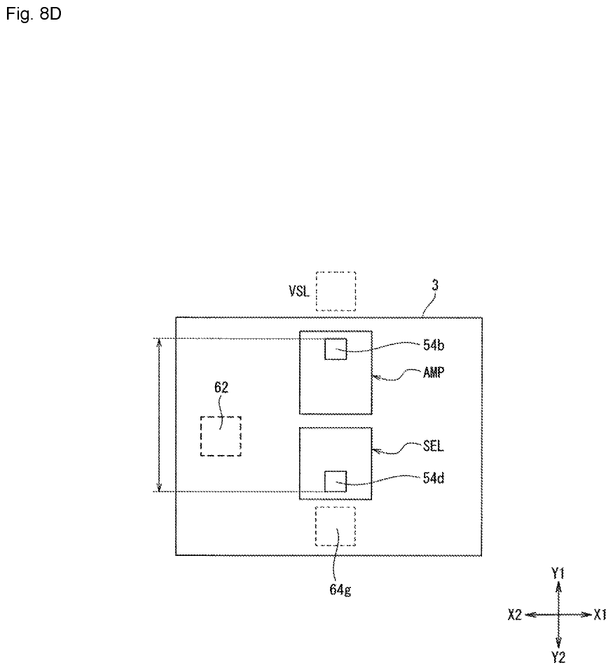

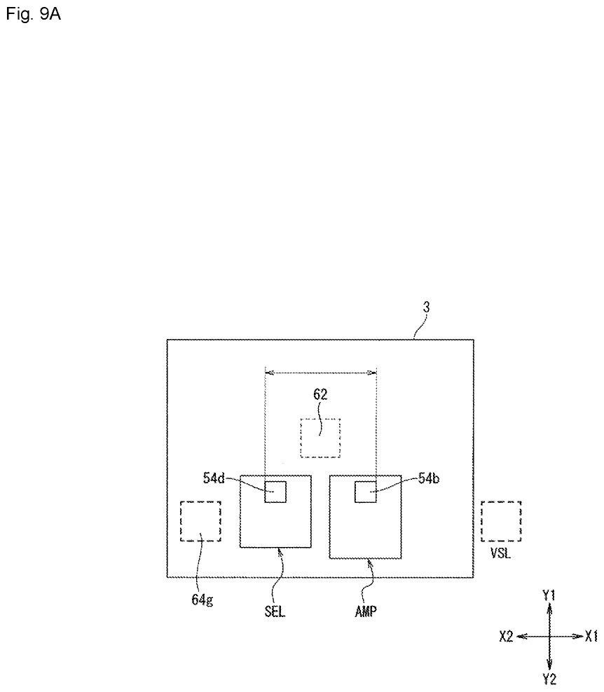

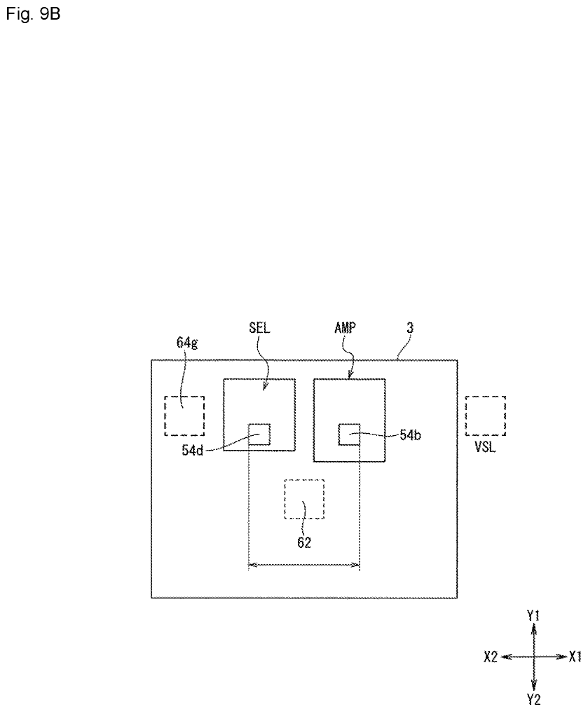

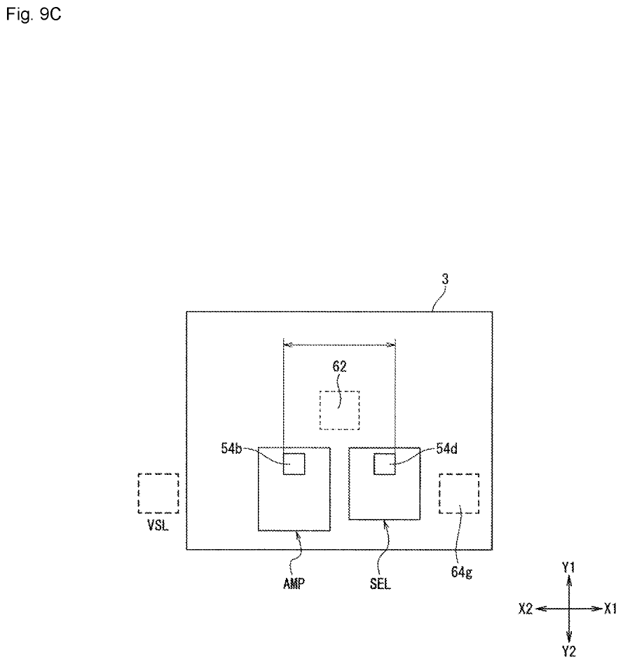

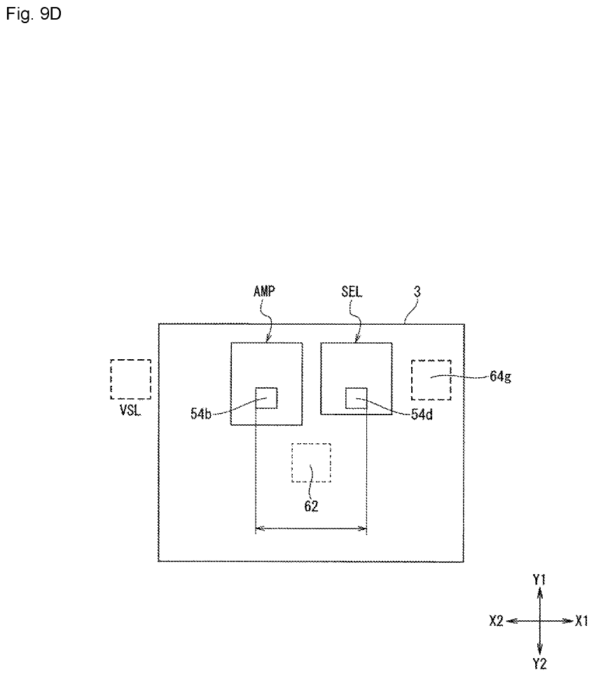

As for the problem described above, according to the first embodiment of the present disclosure, as shown in FIGS. 8A to 8D and 9A to 9D, in plan view, the through-via 62 is provided between the contact portion 54b on the gate electrode 59b of the amplification transistor AMP and the contact portion 54d on the gate electrode 59d of the selection transistor SEL in the area of pixel 3 and in a direction orthogonal to the direction of current passed through the wiring 64b that connects the contact portion 54b of the amplification transistor AMP and the contact portion 54d of the selection transistor SEL. The current is passed from the amplification transistor AMP to the selection transistor SEL.

When the selection transistor SEL is provided in the direction indicated by the arrow Y1 in FIG. 8A and the amplification transistor AMP is provided in the direction indicated by the arrow Y2 in FIG. 8A, the through-via 62 is located between the contact portion 54b on the gate electrode 59b of the amplification transistor AMP and the contact portion 54d on the gate electrode 59d of the selection transistor SEL in the direction indicated by the arrow X1 in FIG. 8A.

When the amplification transistor AMP is provided in the direction indicated by the arrow Y1 in FIG. 8B and the selection transistor SEL is provided in the direction indicated by the arrow Y2 in FIG. 8B, the through-via 62 is located between the contact portion 54b on the gate electrode 59b of the amplification transistor AMP and the contact portion 54d on the gate electrode 59d of the selection transistor SEL in the direction indicated by the arrow X1 in FIG. 8B.

When the selection transistor SEL is provided in the direction indicated by the arrow Y1 in FIG. 8C, and the amplification transistor AMP is provided in the direction indicated by the arrow Y2 in FIG. 8C, the through-via 62 is located between the contact portion 54b on the gate electrode 59b of the amplification transistor AMP and the contact portion 54d on the gate electrode 59d of the selection transistor SEL in the direction indicated by the arrow X2 in FIG. 8C.

When the amplification transistor AMP is provided in the direction indicated by the arrow Y1 in FIG. 8D and the selection transistor SEL is provided in the direction indicated by the arrow Y2 in FIG. 8D, the through-via 62 is located between the contact portion 54b on the gate electrode 59b of the amplification transistor AMP and the contact portion 54d on the gate electrode 59d of the selection transistor SEL, in the direction indicated by the arrow X2 in FIG. 8D.

Meanwhile, when the amplification transistor AMP is provided in the direction indicated by the arrow X1 in FIG. 9A and the selection transistor SEL is provided in the direction indicated by the arrow X2 in FIG. 9A, the through-via 62 is located between the contact portion 54b on the gate electrode 59b of the amplification transistor AMP and the contact portion 54d on the gate electrode 59d of the selection transistor SEL in the direction indicated by the arrow Y1 in FIG. 9A.

When the amplification transistor AMP is provided in the direction indicated by the arrow X1 in FIG. 9B and the selection transistor SEL is provided in the direction indicated by the arrow X2 in FIG. 9B, the through-via 62 is located between the contact portion 54b on the gate electrode 59b of the amplification transistor AMP and the contact portion 54d on the gate electrode 59d of the selection transistor SEL in the direction indicated by the arrow Y2 in FIG. 9B.

When the selection transistor SEL is provided in the direction indicated by the arrow X1 in FIG. 9C and the amplification transistor AMP is provided in the direction indicated by the arrow X2 in FIG. 9C, the through-via 62 is located between the contact portion 54b on the gate electrode 59b of the amplification transistor AMP and the contact portion 54d on the gate electrode 59d of the selection transistor SEL in the direction indicated by the arrow Y1 in FIG. 9C.

When the selection transistor SEL is provided in the direction indicated by the arrow X1 in FIG. 9D and the amplification transistor AMP is placed in the direction indicated by the arrow X2 in FIG. 9D, the through-via 62 is located between the contact portion 54b on the gate electrode 59b of the amplification transistor AMP and the contact portion 54d on the gate electrode 59d of the selection transistor SEL in the direction indicated by the arrow Y2 in FIG. 9D.

For example, in plan view, if the x-coordinate corresponds to the horizontal direction and the y-coordinate corresponds to the vertical direction, and the position coordinates of the contact portion 54b of the amplification transistor AMP are (x1, y1), the position coordinates of the contact portion 54d of the selection transistor SEL are (x2, y2), and the position coordinates of the through-via 62 are (x3, y3), x3 is a value different from x1 and x2, y3 is a value between y1 and y2, or x3 is a value between x1 and x2, and y3 is a value different from y1 and y2.

### Function and Effect According to First Embodiment

As in the foregoing, according to the first embodiment, the pixels 3 are provided at the semiconductor substrate 21, the readout circuit 15 is provided at the semiconductor layer 57, and in the region in the pixel 3, the through-via 62 is provided in a location sufficiently apart from the amplification transistor AMP connected with the charge retention region FD and the selection transistor SEL connected to the vertical signal line (VSL) 11, so that the area required for inter-substrate connection can be reduced as compared to the case in which the through-via 62 is provided in the peripheral region of the semiconductor chip 2, and the influence of the signal lines of adjacent pixels can be reduced without lowering the photoelectric conversion efficiency.

According to the first embodiment, the through-via 62 is provided in a location sufficiently apart from the current passing direction from the amplification transistor AMP to the selection transistor SEL, so that the influence of the signal lines of adjacent pixels can be reduced without lowering the photoelectric conversion efficiency.

Furthermore, according to the first embodiment, the through-via 62 is provided between the contact portion 54b of the amplification transistor AMP and the contact portion 54d of the selection transistor SEL, the path of the FD wiring can be reduced.

### Second Embodiment

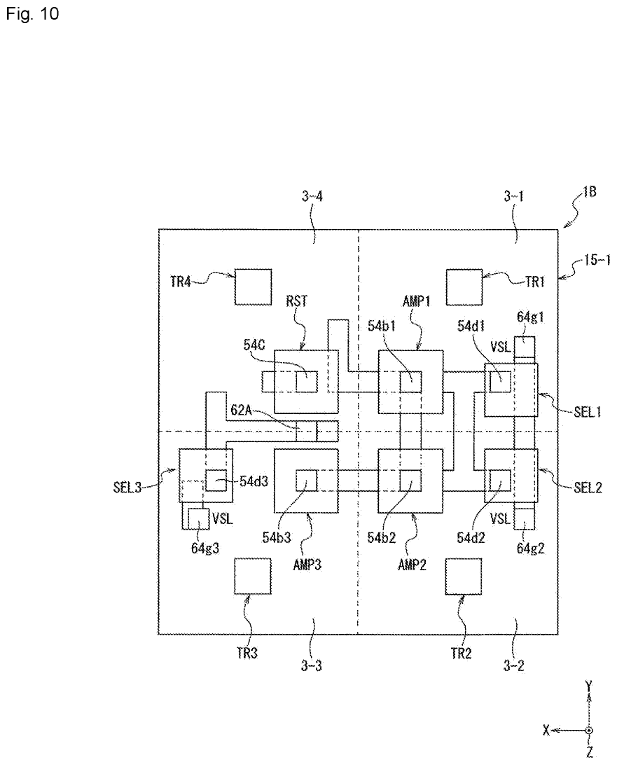

FIG. 10 is a plan view of a readout circuit 15-1 in a 2×2 shared pixel in a light detection device 1B according to a second embodiment of the present disclosure. In FIG. 10, the same parts as those in FIG. 4 are denoted with the same reference characters, and detailed descriptions thereof will not be provided.

The 2×2 shared pixel includes four pixels 3-1, 3-2, 3-3, and 3-4. The pixel 3-1 is provided with a transfer transistor TR1, an amplification transistor AMP1, and a selection transistor SEL1. The transfer transistor TR1, the amplification transistor AMP1, and the selection transistor SEL1 are L-shaped MOSFETs with two channel directions. The amplification transistor AMP1 is provided with a contact portion 54b1 at the gate electrode 59b. The selection transistor SEL1 is provided with a contact portion 54d1 at the gate electrode 59d. The selection transistor SEL1 is connected to a wiring 64g1 connected to a vertical signal line (VSL) 11.

The pixel 3-2 is provided with a transfer transistor TR2, an amplification transistor AMP2, and a selection transistor SEL2. The transfer transistor TR2, the amplification transistor AMP2, and the selection transistor SEL2 are L-shaped MOSFETs with two channel directions. The amplification transistor AMP2 is provided with a contact portion 54b2 at the gate electrode 59b. The selection transistor SEL2 is provided with a contact portion 54d2 at the gate electrode 59d. The selection transistor SEL2 is connected to a wiring 64g2 connected to the vertical signal line (VSL) 11.

The pixel 3-3 is provided with a transfer transistor TR3, an amplification transistor AMP3, and a selection transistor SEL3. The transfer transistor TR3, the amplification transistor AMP3, and the selection transistor SEL3 are L-shaped MOSFETs with two channel directions. The amplification transistor AMP3 is provided with a contact portion 54b3 at the gate electrode 59b. The selection transistor SEL3 is provided with a contact portion 54d3 at the gate electrode 59d. The selection transistor SEL3 is connected to a wiring 64g3 connected to the vertical signal line (VSL) 11.

The pixel 3-4 is provided with a transfer transistor TR4 and a reset transistor RST. The transfer transistor TR4 and the reset transistor RST are L-shaped MOSFETs with two channel directions. The reset transistor RST is provided with a contact portion 54c at the gate electrode 59c.

A through-via 62A is located between the contact area 54b2 of the amplification transistor AMP2 of pixel 3-2 and the contact area 54d3 of the selection transistor SEL3 of pixel 3-3 in the direction indicated by the arrow Y in FIG. 10. In other words, the through-via is located between the amplification transistor AMP3 of pixel 3-3 and the reset transistor RST of the pixel 3-4.

### Function and Effect According to Second Embodiment

As in the foregoing, according to the second embodiment, in the 2×2 shared pixel including multiple pixels 3-1, 3-2, 3-3, and 3-4, the through-via 62A is formed in a location between the contact area 54b2 of the amplification transistor AMP2 of the pixel 3-2 and the contact area 54d3 of the selection transistor SEL3 of the pixel 3-3 and sufficiently apart from the amplification transistor AMP2 and the selection transistor SEL3, so that the influence of the signal lines of adjacent pixels can be reduced without lowering the photoelectric conversion efficiency, the area required for inter-substrate connection is reduced, and the flexibility in positioning of the through-via 62A can be increased within the range of the shared pixels.

### Modification of Second Embodiment

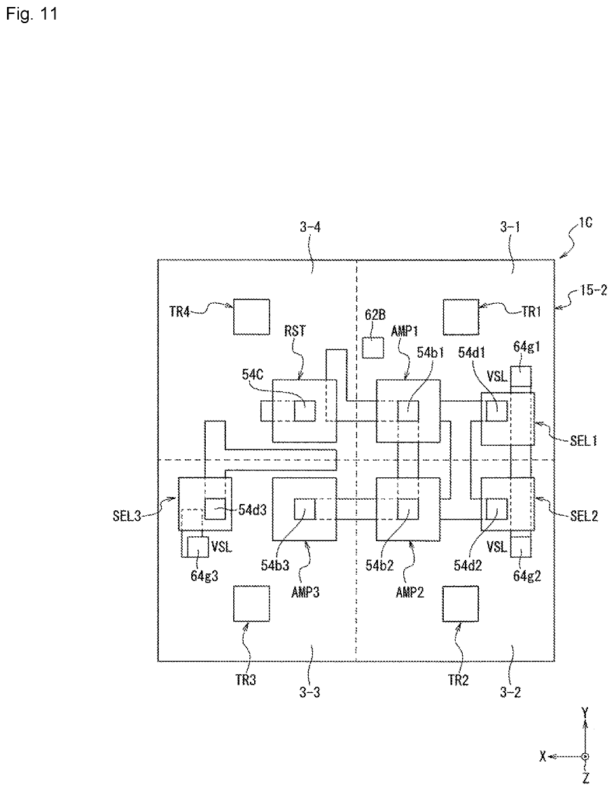

FIG. 11 is a plan view of a readout circuit 15-2 in a 2×2 shared pixel in a light detection device 1C according to a modification of the second embodiment of the present disclosure. In FIG. 11, the same parts as those in FIG. 10 are denoted with the same reference characters, and detailed descriptions thereof will not be provided.

A through-via 62B is provided between the contact portion 54b2 of the amplification transistor AMP2 of the pixel 3-2 and the transfer transistor TR1 of the pixel 3-1 in the direction indicated by the arrow X in FIG. 11. In other words, the through-via is provided between the transfer transistor TR1 of the pixel 3-1 and the transfer transistor TR4 of the pixel 3-4.

### Function and Effect According to Modification of Second Embodiment

As described above, according to the modification of the second embodiment, the same function and effect as those according to the second embodiment can be provided, and the length of the FD wirings can be prevented from being increased.

### Third Embodiment

In the following description of a third embodiment of the present disclosure, fin type MOS transistors are used for a switching transistor FDG, an amplification transistor AMP, a selection transistor SEL, and a reset transistor RST by way of illustration.

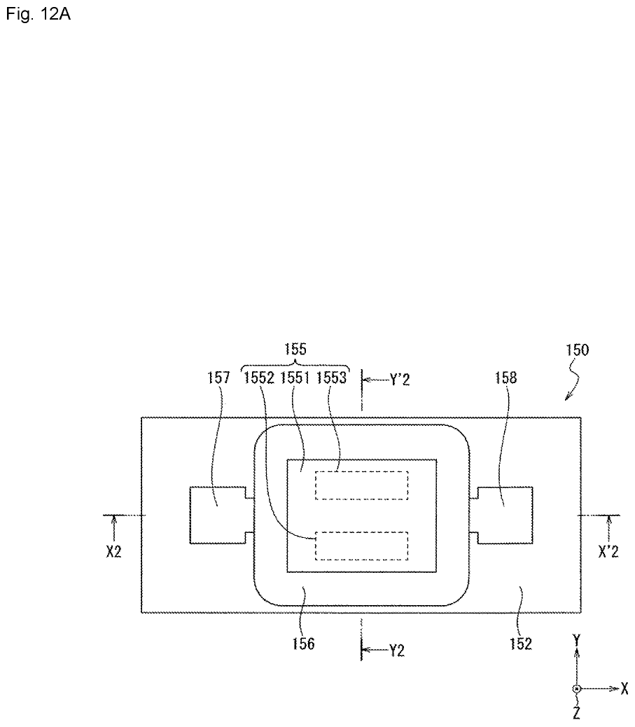

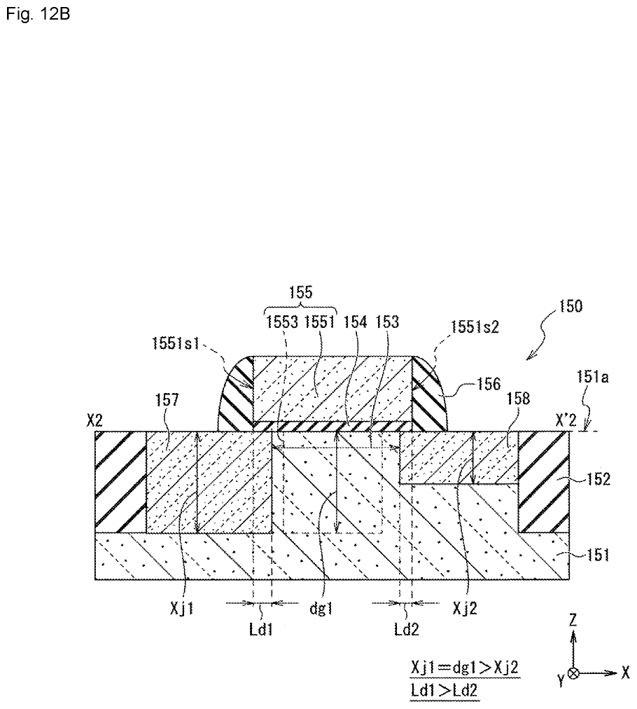

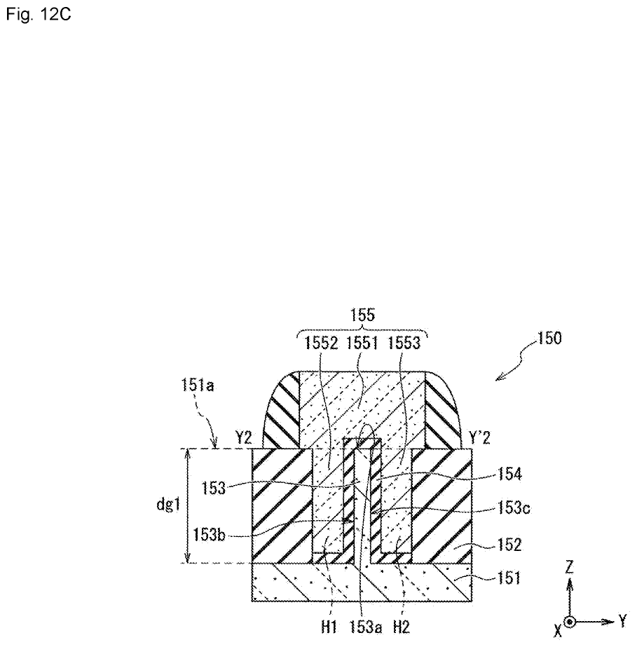

FIG. 12A is a plan view of an exemplary configuration of a MOS transistor 150 according to the third embodiment of the present disclosure. FIGS. 12B and 12C are cross-sectional views of the exemplary configuration of the MOS transistor 150 according to the third embodiment of the present disclosure. FIG. 12B shows a cross section taken along line X2-X2′ in FIG. 12A. FIG. 12C shows a cross section taken along line Y2-Y2′ in FIG. 12A.

As shown in FIGS. 12A to 12C, the MOS transistor 150 is provided on the side of the surface 151a of a semiconductor substrate 151. The semiconductor substrate 151 is for example made of single crystal silicon. The MOS transistor 150 is electrically isolated from other elements by an element isolation layer 152 with an STI (Shallow Trench Isolation) structure provided on the side of the surface 151a of the semiconductor substrate 151. The element isolation layer 152 is an insulating film such as a silicon oxide film (SiO2 film).

The MOS transistor 150 is a first conductivity type (e.g., N-type) MOS transistor. The MOS transistor 150 has a second conductivity type (e.g., P-type) semiconductor region 153 in which a channel is formed, a gate insulating film 154, a gate electrode 155, a sidewall 156, and an N-type source region 157 provided on the semiconductor substrate 151, and an N-type drain region 158 provided on the semiconductor substrate 151.

The semiconductor region 153 is a part of the semiconductor substrate 151 and is made of single crystal silicon. Alternatively, the semiconductor region 153 may be a single crystal silicon layer formed on the semiconductor substrate 151 by the epitaxial growth. The semiconductor region 153 is a portion formed by etching a part of the semiconductor substrate 151 on the side of the surface 151a and has a fin shape. The semiconductor region 153 has for example a shape shorter in the X-axis direction.

As shown in FIG. 12C, the semiconductor region 153 has an upper surface 153a and side surfaces 153b and 153c. The upper surface 153a is a part of the surface 151a of the semiconductor substrate 151. The upper surface 153a is a horizontal plane parallel to the X-axis and Y-axis directions. The side surface 153b is located on one side (left side in FIG. 2C) of the upper surface 153a in the Y-axis direction. The side surface 153c is located on the other side (right side in FIG. 2C) of the upper surface 153a in the Y-axis direction. The side surfaces 153b and 153c are planes that intersect the horizontal plane and are vertical planes parallel to the X-axis and Z-axis directions.

In the Y-axis direction, a trench H1 is provided on one side of the semiconductor region 153, and a trench H2 is provided at the other side of the semiconductor region 153. A second part 1552 of the gate electrode 155 is provided in the trench H1. A third part 1553 of the gate electrode 155 is disposed in the trench H2. The second part 1552 and the third part 1553 will be described later. The semiconductor region 153 is sandwiched between the second part 1552 provided in the trench H1 and the third part 1553 provided in the trench H2 in the left-right direction.

The gate insulating film 154 is provided so as to continuously cover the upper surface 153a and side surfaces 153b and 153c of the semiconductor region 153. The gate insulating film 154 may be a SiO2 film.

The gate electrode 155 covers the semiconductor region 153 through the gate insulating film 154. For example, the gate electrode 155 has a first part 1551, which faces the upper surface 153a of the semiconductor region 153 through the gate insulating film 154, the second part 1552, which faces the side surface 153b of the semiconductor region 153 through the gate insulating film 154, and the third part 1553, which faces the side surface 153c of the semiconductor region 153 through the gate insulating film 154. The second part 1552 and the third part 1553 are connected to a bottom face of the first part 1551. Note that the first part 1551 may be called a “horizontal gate electrode”. The second part 1552 and the third part 1553 may each be called a “vertical gate electrode”.

As a result, the gate electrode 155 can apply gate voltage to the upper surface 153a and the side surfaces 153b and 153c of the semiconductor region 153 simultaneously. In other words, the gate electrode 155 can apply gate voltage to the semiconductor region 153 simultaneously in three directions, i.e., from the upper side and both the left and right sides. As a result, the gate electrode 155 can deplete the semiconductor region 153 completely. The gate electrode 155 may be a polysilicon (Poly-Si) film.

### Function and Effect According to Third Embodiment

As in the foregoing, according to the third embodiment, the cross-sectional area of the channel with respect to the current direction (e.g., in the X-axis direction) can be increased and the on-resistance can be reduced as compared to planar MOS transistors.

### Fourth Embodiment

In the following description of a fourth embodiment of the present disclosure, a GAA (Gate All Around) MOS transistor having four channels is used for a switching transistor FDG, an amplification transistor AMP, a selection transistor SEL, and a reset transistor RST by way of illustration.

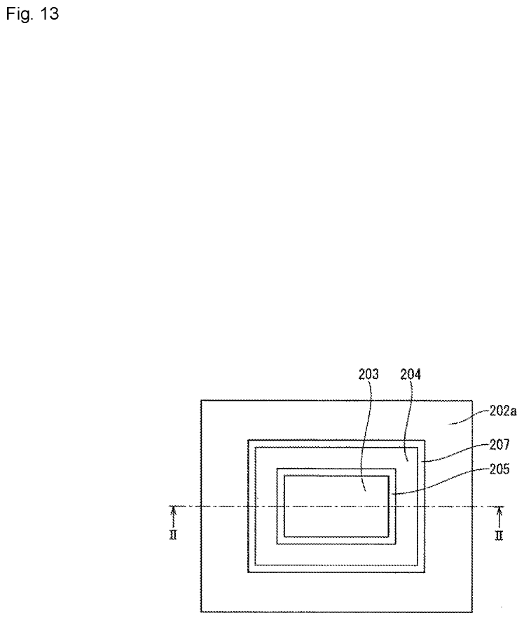

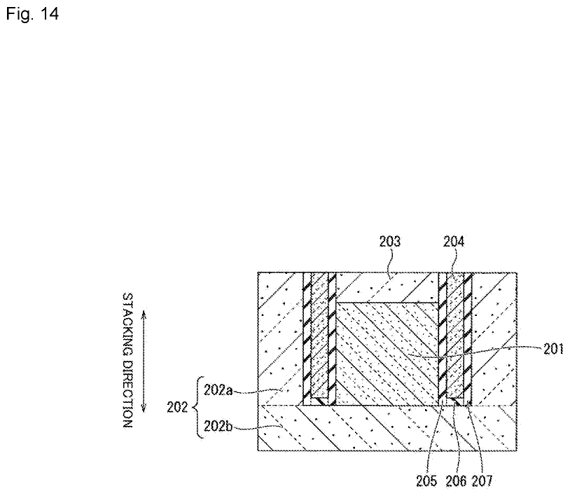

FIG. 13 is a plan view of a configuration of a MOS transistor according to a fourth embodiment of the present disclosure. FIG. 14 is a cross-sectional view taken along line II-II in FIG. 13.

As shown in FIGS. 13 and 14, the MOS transistor has a low concentration N-type region 201, a first high concentration N-type region 202, a second high concentration N-type region 203, a gate electrode 204, a first insulating film 205, a second insulating film 206, and a third insulating film 207.

The two surfaces of a rectangular parallelepiped formed by the low-concentration N-type region 201 that are not adjacent to each other each form a plane when viewed in the stacking direction shown in FIG. 14.

Therefore, the shape of the low-concentration N-type region 201 is rectangular when viewed in the stacking direction.

The first high concentration N-type region 202 is formed using a material having a higher impurity concentration than the low concentration N-type region 201. The first high concentration N-type region 202 is formed to include an opposing region 202a and a bottom region 202b.

The opposing region 202a is opposed to the low concentration N-type region 201 with the gate electrode 204 therebetween.

The bottom region 202b includes a part in contact with one of two surfaces of the low concentration N-type region 201 which are not adjacent to each other (the lower surface in FIG. 14) and a part opposed to the gate electrode 204 in the stacking direction.

The first high concentration N-type region 202 is connected to one of the source electrode and the drain electrode. In the following description of the fourth embodiment, the opposing region 202a of the first high-concentration N-type region 202 is connected to the drain electrode as illustrated.

In the following description, a second high concentration N-type region 203 is formed using a material having a higher impurity concentration than the low concentration N-type region 201.

The second high concentration N-type region 203 is in contact with the other (the upper surface in FIG. 14) of the two surfaces of the low concentration N-type region 201 that are not adjacent to each other.

As described above, the first high-concentration N-type region 202 and the second high-concentration N-type region 203 are stacked on the low-concentration N-type region 201 with the low-concentration N-type region 201 therebetween and have a higher impurity concentration than the low-concentration N-type region 201.

The second high concentration N-type region 203 is connected to the other of the source and drain electrodes. In the following description of the fourth embodiment, the second high concentration N-type region 203 is connected to the source electrode as illustrated.

The surface of the second high concentration N-type region 203 connected to the source electrode and the surface of the opposing region 202a connected to the drain electrode are flush with each other (at the level of the silicon surface) when viewed in a direction orthogonal to the stacking direction.

Therefore, the surface of the first high-concentration N-type region 202 connected to the source electrode or the drain electrode and the surface of the second high-concentration N-type region 203 connected to the source electrode or the drain electrode are flush with each other when viewed in the direction orthogonal to the stacking direction.

The gate electrode 204 surrounds the low-concentration N-type region 201 when viewed in the stacking direction (the up-down direction in FIG. 14).

The gate electrode 204 has a part that is not opposed to the low-concentration N-type region 201. In other words, the low-concentration N-type region 201 has a part that is not opposed to the gate electrode 204.

The first insulating film 205 is provided between the gate electrode and the low concentration N-type region 201.

The second insulating film 206 is provided between the gate electrode and the first high concentration N-type region 202.

The third insulating film 207 is provided between the opposing region 202a and the gate electrode.

The MOS transistor according to the fourth embodiment has a distribution of a layer with a higher impurity concentration (first high concentration N-type region 202), a layer with a lower impurity concentration (low concentration N-type region 201), and a layer with a higher impurity concentration (second high concentration N-type region 203) in the vertical direction in the region below the silicon surface. In addition, the MOS transistor according to the fourth embodiment has a GAA structure in which the low concentration N-type region 201 is surrounded by gate insulating films (a first insulating film 205, a second insulating film 206, and a third insulating film 207) and the gate electrode 204.

Therefore, current is passed in the up-down direction (stacking direction) from the source electrode to which the second high concentration N-type region 203 is connected, through the channel (channel region) formed by the low concentration N-type region 201, to the first high concentration N-type region 202 (bottom region 202b) connected to the drain electrode. The current is then passed through the channel in the bottom region 202b to the drain electrode in the opposing region 202a.

### Function and Effect According to Fourth Embodiment

As described above, according to the fourth embodiment, the same function and effect as those according to the first embodiment can be provided.

### Fifth Embodiment

A fifth embodiment of the present disclosure will be described with reference to an example of application to a three-layer stacked pixel arrangement.

### <Functional Configuration of Light Detection Device>

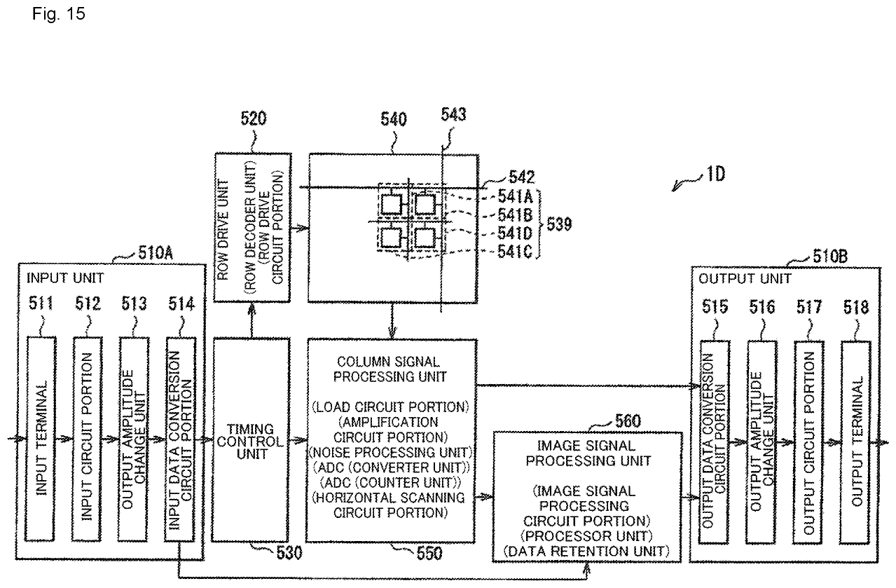

FIG. 15 is a block diagram of an exemplary functional configuration of a light detection device 1D according to the fifth embodiment of the present disclosure.

The light detection device 1D in FIG. 15 includes, for example, an input unit 510A, a row drive unit 520, a timing control unit 530, a pixel array portion 540, a column signal processing unit 550, an image signal processing unit 560, and an output unit 510B.

The pixel array portion 540 includes pixels 541 repeatedly arranged in an array. More specifically, a shared pixel unit 539 including a plurality of pixels is a repeating unit, which is repeatedly arranged in an array that has a row direction and a column direction. For the sake of convenience, the row direction may be referred to as the H direction and the column direction orthogonal to the row direction as the V direction. In the example shown in FIG. 15, one shared pixel unit 539 includes four pixels (pixels 541A, 541B, 541C, and 541D).

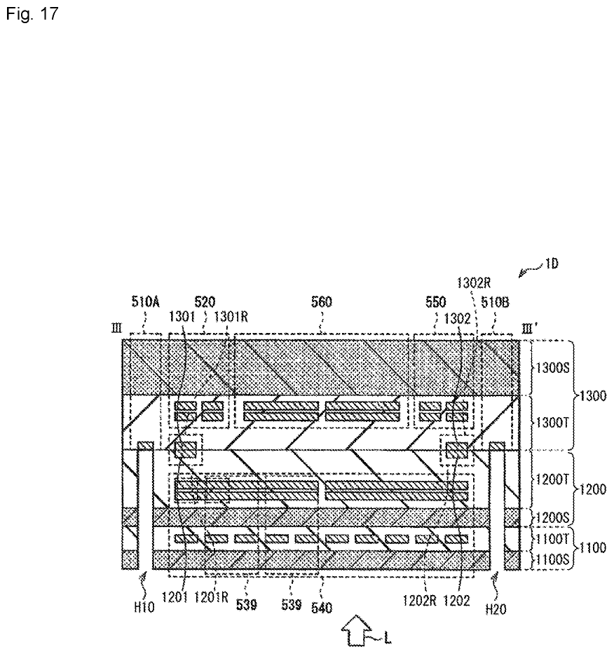

The pixels 541A, 541B, 541C, and 541D each have a photodiode PD. The shared pixel unit 539 is a unit that shares one pixel circuit (pixel circuit 1210 in FIG. 17 which will be described). In other words, four pixels (pixels 541A, 541B, 541C, and 541D) have one pixel circuit (pixel circuit 1210 which will be described). The pixel circuit is operated in a time-division manner, so that the pixel signals of the pixels 541A, 541B, 541C, and 541D are sequentially read out. The pixels 541A, 541B, 541C, and 541D are arranged for example in 2 rows×2 columns. Along with the pixels 541A, 541B, 541C, and 541D, a plurality of row drive signal lines 542 and a plurality of vertical signal lines (column readout lines) 543 are provided in the pixel array portion 540.

The row drive signal lines 542 drive the pixels 541 included in each of the plurality of shared pixel units 539, which are arranged side by side in the row direction in the pixel array portion 540. Among the shared pixel units 539, pixel arrayed side by side in the row direction are driven. A plurality of transistors are provided in the shared pixel unit 539. To drive these multiple transistors, multiple row drive signal lines 542 are connected to one shared pixel unit 539. The vertical signal lines (row readout lines) 543 are connected with the shared pixel unit 539. Pixel signals are read out from the pixels 541A, 541B, 541C, and 541D included in the shared pixel unit 539 through the vertical signal lines (column readout lines) 543.

The row drive unit 520 includes, for example, a row address control unit that determines a row position for driving pixels, in other words, a row decoder unit, and a row driving circuit portion that generates signals to drive the pixels 541A, 541B, 541C, and 541D.

The column signal processing unit 550 includes, for example, a load circuit portion that is connected to the vertical signal line 543 and forms a source follower circuit with the pixels 541A, 541B, 541C, and 541D (the shared pixel unit 539). The column signal processing unit 550 may have an amplifying circuit portion that amplifies signals read out from the shared pixel unit 539 through the vertical signal line 543. The column signal processing unit 550 may have a noise processing unit. In the noise processing unit, for example, the noise level of the system is removed from the signals read out from the shared pixel unit 539 as a result of photoelectric conversion.

The column signal processing unit 550 has, for example, an analog-to-digital converter (ADC). The analog-to-digital converter converts a signal read out from the shared pixel unit 539 or the above noise processed analog signal into a digital signal. The ADC includes, for example, a comparator unit and a counter unit. The comparator unit compares an analog signal as a conversion target with a reference signal as a comparison target. The counter unit measures the time until the comparison result in the comparator unit is inverted. The column signal processing unit 550 may include a horizontal scanning circuit portion that controls scanning of a column to be read out.

The timing control unit 530 provides signals to the row drive unit 520 and the column signal processing unit 550 to control timing on the basis of reference clock signals and timing control signals input to the device.

The image signal processing unit 560 is a circuit that performs various kinds of signal processing on data obtained as a result of photoelectric conversion, in other words, data obtained as a result of imaging operation by the imaging device 1. The image signal processing unit 560 includes, for example, an image signal processing circuit portion and a data storage unit. The image signal processing unit 560 may also include a processor unit.

An example of signal processing performed in the image signal processing unit 560 is tone curve correction processing, in which AD-converted captured data is given an increased tonal range when the captured data has a dark subject and a reduced tonal range when the captured data has a bright subject. In this case, it is desirable to store in advance, in the data storage unit of the image signal processing unit 560, characteristic data about tone curves for determining which tone curve to base correction of the tones of the captured data on.

The input unit 510A is used for example to input the above reference clock signal, timing control signal, and characteristic data from outside the device to the imaging device 1. The timing control signals may include vertical synchronization signals and horizontal synchronization signals. The characteristic data is data to be stored in the data storage unit of the image signal processing unit 560. The input unit 510A includes, for example, an input terminal 511, an input circuit portion 512, an input amplitude change unit 513, an input data conversion circuit portion 514, and a power supply unit (not shown).

The input terminal 511 is an external terminal for inputting data. The input circuit portion 512 is configured to take signals input to the input terminal 511 into the imaging device 1. The input amplitude change unit 513 changes the amplitude of a signal taken in by the input circuit portion 512 into an amplitude that is easy to use inside the imaging device 1. The input data conversion circuit portion 514 changes the order of the data sequence of the input data. The input data conversion circuit portion 514 includes for example a serial-to-parallel conversion circuit. In the serial-to-parallel conversion circuit, serial signals received as input data are converted to parallel signals. In the input unit 510A, the input amplitude change unit 513 and the input data conversion circuit portion 514 may be omitted. The power supply unit provides a power supply set to various voltage levels required inside the light detection device 1D on the basis of power externally supplied to the light detection device 1D.

When the light detection device 1D is connected to an external memory device, the input unit 510A may be provided with memory interface circuitry to receive data from the external memory device. Examples of the external memory device include a flash memory, an SRAM and a DRAM.

The output unit 510B outputs image data to an external device. This image data is, for example, image data captured by the imaging device 1 and image data processed by the image signal processing unit 560. The output unit 510B include for example an output data conversion circuit portion 515, an output amplitude change unit 516, an output circuit portion 517, and an output terminal 518.

The output data conversion circuit portion 515 includes for example a parallel-serial conversion circuit, and in the output data conversion circuit portion 515, parallel signals used inside the light detection device 1D are converted to serial signals. The output amplitude change unit 516 changes the amplitude of a signal used inside the light detection device 1D. The amplitude-changed signal is easier to use in an external device connected to the light detection device 1D. The output circuit portion 517 is a circuit that outputs data from inside the light detection device 1D to outside the device, and an external wiring which is outside the light detection device 1D and connected to the output terminal 518 is driven by the output circuit portion 517. At the output terminal 518, data is output from the imaging device 1 to outside the device. In the output unit 510B, the output data conversion circuit portion 515 and the output amplitude change unit 516 may be omitted.

When the light detection device 1D is connected to an external memory device, the output unit 510B may be provided with a memory interface circuit that outputs data to the external memory device. Examples of the external memory device include a flash memory, an SRAM, and a DRAM.

### (General Configuration of Light Detection Device)

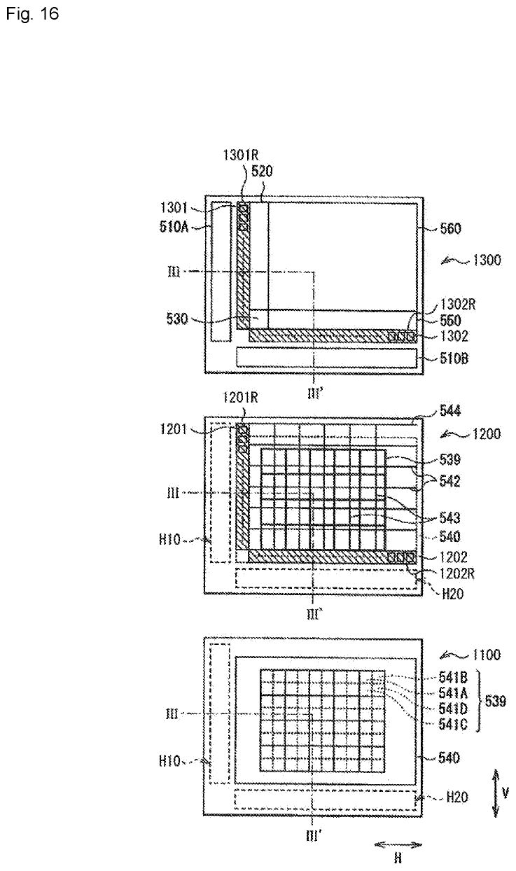

FIGS. 16 and 17 show an exemplary configuration of the light detection device 1D. The light detection device 1D includes three substrates (a first substrate 1100, a second substrate 1200, and a third substrate 1300). FIG. 16 schematically illustrates a planar configuration of each of the first substrate 1100, the second substrate 1200, and the third substrate 1300, and FIG. 17 schematically illustrates a cross-sectional configuration of the first substrate 1100, the second substrate 1200, and the third substrate 1300 stacked on each other.

FIG. 17 corresponds to the cross-sectional configuration along line III-III′ shown in FIG. 16. The light detection device 1D is a three-dimensional structure including the three substrates (the first substrate 1100, the second substrate 1200, and the third substrate 1300) bonded together. The first substrate 1100 includes a semiconductor layer 1100S and a wiring layer 1100T. The second substrate 1200 includes a semiconductor layer 1200S and a wiring layer 1200T. The third substrate 1300 includes a semiconductor layer 1300S and a wiring layer 1300T. Here, the wirings included in the first substrate 1100, the second substrate 1200, and the third substrate 1300 together with the interlayer insulating film that surrounds the wirings are referred to as the wiring layers (1100T, 1200T, 1300T) on the respective substrates (the first substrate 1100, the second substrate 1200, and the third substrate 1300) for the sake of convenience.

The first substrate 1100, the second substrate 1200 and the third substrate 1300 are stacked in this order, with the semiconductor layer 1100S, the wiring layer 1100T, the semiconductor layer 1200S, the wiring layer 1200T, the wiring layer 1300T, and the semiconductor layer 1300S in the stacking direction. The specific configurations of the first substrate 1100, the second substrate 1200, and the third substrate 1300 will be described later. The arrows shown in FIG. 17 represent the direction of incidence of light L into the light detection device 1D. Herein, the light incident side in the light detection device 1D may be referred to as “bottom,” “lower side,” or “downward” and the side opposite the light incident side as “up,” “upper side,” or “upward” in the subsequent cross-sectional views for the sake of convenience. Also herein, with respect to a substrate including a semiconductor layer and a wiring layer, the side of the wiring layer may be referred to as the front surface, and the side of the semiconductor layer as the back surface for the sake of convenience. The description in the specification is not limited to the above-described terminology. The light detection device 1D is for example a back-illumination type light detection device in which light is incident from the back side of the first substrate 1100 having a photodiode.

Both the pixel array portion 540 and the shared pixel unit 539 included in the pixel array portion 540 are formed using both the first substrate 1100 and the second substrate 1200. The first substrate 1100 has a plurality of pixels 541A, 541B, 541C, and 541D of the shared pixel unit 539. Each of the pixels 541 has a photodiode (photodiode PD in the following description) and a transfer transistor (transfer transistor TR in the following description). The second substrate 1200 is provided with a pixel circuit 1210 that has a shared pixel unit 539.

The pixel circuit 1210 reads out pixel signals transferred from the photodiodes of each of pixels 541A, 541B, 541C, and 541D through the transfer transistors or resets the photodiodes. In addition to the pixel circuits 1210, the second substrate 1200 has a plurality of row drive signal lines 542 extending in the row direction and a plurality of vertical signal lines 543 extending in the column direction. The second substrate 1200 further has a power supply line 544 extending in the row direction. The third substrate 1300 has for example an input unit 510A, a row drive unit 520, a timing control unit 530, a column signal processing unit 550, an image signal processing unit 560, and an output unit 510B.

The row drive unit 520 has a part provided in a region overlapping the pixel array portion 540 in the stacking direction of the first substrate 1100, the second substrate 1200, and the third substrate 1300 (hereinafter simply referred to as the stacking direction). More specifically, the row drive unit 520 is provided in the stacking direction in an area overlapping the vicinity of the edge of the pixel array portion 540 in the H direction (FIG. 16). The column signal processing unit 550 has for example a part provided in a region overlapping the pixel array portion 540 in part in the stacking direction. More specifically, the column signal processing unit 550 is provided, in the stacking direction, in a region overlapping the vicinity of the edge of the pixel array portion 540 in the V direction (FIG. 16). Although not shown, the input unit 510A and the output unit 510B may be provided in locations other than the third substrate 1300, for example, on the second substrate 1200. Alternatively, the input unit 510A and output unit 510B may be provided on the back surface side (light-incident surface) of the first substrate 1100. The pixel circuit 1210 provided on the above second substrate 1200 may also be referred to as a pixel transistor circuit, a pixel transistor group, a pixel transistor, a pixel readout circuit or a readout circuit in some cases.

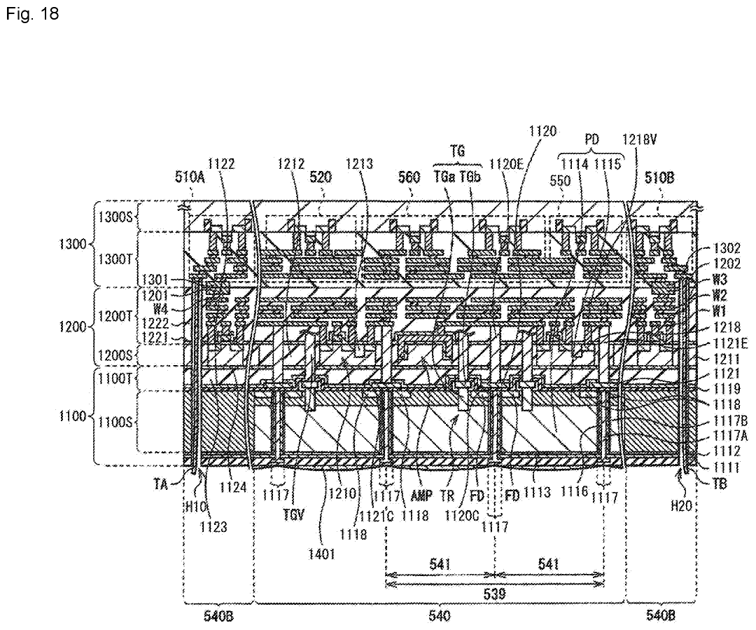

The first substrate 1100 and the second substrate 1200 are electrically connected for example by through-hole electrodes (through-hole electrodes 1120E and 1121E in FIG. 18 which will be described). The second substrate 1200 and the third substrate 1300 are electrically connected for example through contact portions 1201, 1202, 1301, and 1302. The contact portions 1201 and 1202 are provided on the second substrate 1200, and the contact portions 1301 and 1302 are provided on the third substrate 1300. The contact portion 1201 of the second substrate 1200 is in contact with the contact portion 1301 of the third substrate 1300, and the contact portion 1202 of the second substrate 1200 is in contact with the contact portion 1302 of the third substrate 1300.

The second substrate 1200 has a contact region 1201R with a plurality of contact portions 1201 and a contact region 1202R with a plurality of contact portions 1202. The third substrate 1300 has a contact region 1301R provided with a plurality of contact portions 1301 and a contact region 1302R provided with a plurality of contact portions 1302. The contact regions 1201R and 1301R are provided between the pixel array portion 540 and the row drive unit 520 in the stacking direction (FIG. 17). In other words, the contact regions 1201R are 1301R are provided for example in or near the region where the row drive unit 520 (third substrate 1300) and the pixel array portion 540 (second substrate 1200) overlap in the stacking direction. The contact regions 1201R and 1301R are for example located at the end of the region in the H direction (FIG. 16).

In the third substrate 1300, for example, the contact regions 1301R are located in a part of the row drive unit 520, specifically in a location overlapping the end of the row drive unit 520 in the H direction (FIGS. 16 and 17). The contact portions 1201, 1301, for example, connect the row drive unit 520 on the third substrate 1300 and the row drive signal line 542 on the second substrate 1200. The contact portions 1201 and 1301 may for example connect the input unit 510A provided on the third substrate 1300 to the power supply line 544 and a reference potential line (reference potential line VSS which will be described).

The contact regions 1202R and 1302R are provided between the pixel array portion 540 and the column signal processing unit 550 in the stacking direction (FIG. 17). In other words, the contact regions 1202R and 1302R are provided for example in or near the area where the column signal processing unit 550 (third substrate 1300) and the pixel array portion 540 (second substrate 1200) overlap in the stacking direction. The contact regions 1202R and 1302R are for example located at the end of the region in the V direction (FIG. 16). In the third substrate 1300, the contact regions 1301R are located for example in a part of the column signal processing unit 550, specifically in a location overlapping the end of the column signal processing unit 550 in the V direction (FIGS. 16 and 17).

The contact portions 1202 and 1302 are used for example to connect pixel signals (signals corresponding to the amount of charge generated as a result of photoelectric conversion in the photodiodes) output from the plurality of shared pixel units 539 of the pixel array portion 540 to the column signal processing unit 550 provided on the third substrate 1300. The pixel signals are sent from the second substrate 1200 to the third substrate 1300.

FIG. 17 is an example of a cross-sectional view of the light detection device 1D as described above. The first substrate 1100, the second substrate 1200, and the third substrate 1300 are electrically connected through the wiring layers 1100T, 1200T, and 1300T. For example, the light detection device 1D has an electrical connection that electrically connects the second substrate 1200 and the third substrate 1300. Specifically, the contact portions 1201, 1202, 1301, and 1302 are formed using electrodes made of a conductive material. The conductive material may be made of a metal material such as copper (Cu), aluminum (Al), and gold (Au). The contact regions 1201R, 1202R, 1301R, and 1302R electrically connect the second substrate 1200 and the third substrate 1300 for example by directly connecting wirings formed as electrodes, thereby enabling signal input and/or output between the second substrate 1200 and the third substrate 1300.

The electrical connection that electrically connects the second substrate 1200 and the third substrate 1300 can be provided at a desired location. For example, as described in connection with the contact regions 1201R, 1202R, 1301R, and 1302R in FIG. 17, the electrical connection can be provided in an area overlapping the pixel array portion 540 in the stacking direction. The electrical connection may also be provided in a region that does not overlap the pixel array portion 540 in the stacking direction. Specifically, the electrical connection may be provided in a peripheral portion provided outside of the pixel array portion 540 and in an area overlapping the pixel array portion 540 in the stacking direction.

For example, the first substrate 1100 and the second substrate 1200 are provided with connection holes H10 and H20. The connection holes H10 and H20 penetrate through the first substrate 1100 and the second substrate 1200 (FIG. 17). The connection holes H10 and H20 are provided outside the pixel array portion 540 (or the part overlapping the pixel array portion 540) (FIG. 16).

For example, the connection hole H10 is provided outside the pixel array portion 540 in the H direction, and the connection hole H20 is provided outside the pixel array portion 540 in the V direction. For example, the connection hole H10 reaches the input unit 510A on the third substrate 1300, and the connection hole H20 reaches the output unit 510B on the third substrate 1300. The connection holes H10 and H20 may be hollow or may at least partially include a conductive material. For example, there may be a configuration that includes electrodes formed as the input unit 510A and/or the output unit 510B and bonding wires connected to the electrodes. Alternatively, there may be a configuration that includes the electrodes formed as the input unit 510A and/or the output unit 510B and a conductive material provided in the connection holes H10 and H20 connected to the electrodes. The conductive material provided in the connection holes H10 and H20 may be embedded in part or all of the connection holes H10 and H20, or the conductive material may be formed on the side walls of the connection holes H10 and H20.

Although in the structure shown in FIG. 17, the third substrate 1300 is provided with the input unit 510A and the output unit 510B, the structure is not limited to the above. For example, the input unit 510A and/or the output unit 510B can be provided on the second substrate 1200 by sending the signals of the third substrate 1300 to the second substrate 1200 through the wiring layers 1200T and 1300T. Similarly, the input unit 510A and/or the output unit 510B can be provided on the first substrate 1100 by sending the signals of the second substrate 1200 to the first substrate 1100 through the wiring layers 1100T and 1200T.

### (Specific Configuration of Light Detection Device)

FIG. 18 is an example of a cross-sectional view perpendicular to the main surfaces of the first substrate 1100, the second substrate 1200, and the third substrate 1300 of the light detection device 1D. FIG. 18 is a schematic representation to make the positional relationship of the elements easier to understand and may be different from an actual cross-section. In the light detection device 1D, the first substrate 1100, the second substrate 1200, and the third substrate 1300 are stacked in this order. The light detection device 1D further has a light receiving lens 1401 on the back surface side (light incident side) of the first substrate 1100. A color filter layer (not shown) may be provided between the light receiving lens 1401 and the first substrate 1100. The light receiving lens 1401 is provided for each of the pixels 541A, 541B, 541C, and 541D. The light detection device 1D is a back side illumination type imaging device. The light detection device 1D has a pixel array portion 540 located in the center and a peripheral portion 540B located outside of the pixel array portion 540.

The first substrate 1100 has, in order from the light receiving lens 1401 side, an insulating film 1111, a fixed charge film 1112, a semiconductor layer 1100S, and a wiring layer 1100T. The semiconductor layer 1100S is for example made of a silicon substrate. The semiconductor layer 1100S has for example a p-well layer 1115 on and near a part of the surface (the surface on the side of the wiring layer 1100T) and an n-type semiconductor region 1114 in the other region (deeper than the p-well layer 1115). For example, the n-type semiconductor region 1114 and the p-well layer 1115 constitute a pn-junction type photodiode PD. The p-well layer 1115 is a p-type semiconductor region.

A floating diffusion FD and a VSS contact region 1118 are provided near the surface of the semiconductor layer 1100S. The floating diffusion FD is made of an n-type semiconductor region provided in the p-well layer 1115. The floating diffusion FD is connected from the first substrate 1100 to the second substrate 1200 (more specifically, from the wiring layer 1100T to the wiring layer 1200T) through electrical means (a through-hole electrode 1120E which will be described). On the second substrate 1200 (more specifically, inside the wiring layer 1200T), the floating diffusion FD is electrically connected to the gate of the amplification transistor AMP and the source of the switching transistor FDG by the electrical means.

The VSS contact region 1118 is electrically connected to the reference potential line VSS and is spaced apart from the floating diffusion FD. The VSS contact region 1118 is for example made of a p-type semiconductor region. The VSS contact region 1118 is connected to a ground potential or a fixed potential. In this way, a reference potential is supplied to the semiconductor layer 1100S.

A transfer transistor TR is provided on the first substrate 1100, along with the photodiode PD, the floating diffusion FD and the VSS contact region 1118. The photodiode PD, the floating diffusion FD, the VSS contact region 1118, and the transfer transistor TR are provided in each of pixels 541A, 541B, 541C and 541D. The transfer transistor TR is provided on the front surface side (opposite to the light incident side or the side of the second substrate 1200) of the semiconductor layer 1100S.

The transfer transistor TR has a transfer gate TG. The transfer gate TG includes for example a horizontal portion TGb opposed to the surface of the semiconductor layer 100S and a vertical portion TGa provided in the semiconductor layer 1100S. The vertical portion TGa extends in the thickness-wise direction of the semiconductor layer 1100S. One end of the vertical portion TGa is in contact with the horizontal portion TGb, and the other end is within the n-type semiconductor region 1114. The transfer transistor TR is formed as such a vertical transistor, so that pixel signal transfer failures are less likely to occur and the readout efficiency of pixel signals can be improved.

The semiconductor layer 1100S is provided with pixel isolation portions 1117 that isolate the pixels 541A, 541B, 541C, and 541D from each other. The pixel isolation portions 1117 are formed to extend in a normal direction (perpendicular to the surface of the semiconductor layer 1100S) to the semiconductor layer 1100S. The pixel isolation portions 1117 for example electrically and optically isolate the pixels 541A, 541B, 541C, and 541D from each other. The pixel isolation portion 1117 includes for example a light shielding film 1117A and an insulating film 1117B. For example, tungsten (W) is used for the light shielding film 1117A. The insulating film 1117B is provided between the light shielding film 1117A and the p-well layer 1115 or the n-type semiconductor region 1114. The insulating film 1117B is made of for example, silicon oxide (SiO). The pixel isolation portion 1117 has for example, a full trench isolation (FTI) structure and penetrates through the semiconductor layer 1100S. Although not shown, the pixel isolation portion 1117 is not limited to such an FTI structure that penetrates through the semiconductor layer 1100S. For example, the portion may have a deep trench isolation (DTI) structure that does not penetrate through the semiconductor layer 1100S. The pixel isolation portion 1117 extends in the normal direction to the semiconductor layer 1100S and is formed in a region of the semiconductor layer 1100S.

The semiconductor layer 1100S is for example provided with a first pinning region 1113 and a second pinning region 1116. The first pinning region 1113 is provided near the back surface of the semiconductor layer 1100S and is located between the n-type semiconductor region 1114 and the fixed charge film 1112. The second pinning region 1116 is provided on a side surface of the pixel isolation portion 1117, specifically between the pixel isolation portion 1117 and the p-well layer 1115 or the n-type semiconductor region 1114. The first pinning region 1113 and the second pinning region 1116 is for example made of a p-type semiconductor region.

The fixed charge film 1112 having negative fixed charge is provided between the semiconductor layer 1100S and the insulating film 1111. An electric field induced by the fixed charge film 1112 forms the first pinning region 1113 of a hole storage layer at the interface on the light receiving surface (back surface) side of the semiconductor layer 1100S. This suppresses the generation of dark current attributable to interface states on the side of the light receiving surface of the semiconductor layer 1100S. The fixed charge film 1112 is for example made of an insulating film having negative fixed charge. Examples of the material of such an insulating film having the negative fixed charge include hafnium oxide, zirconium oxide, aluminum oxide, titanium oxide, and tantalum oxide.

A light shielding film 1117A is provided between the fixed charge film 1112 and the insulating film 1111. The light shielding film 1117A may be provided continuously with the light shielding film 1117A that forms the pixel isolation portion 1117. The light shielding film 1117A between the fixed charge film 1112 and the insulating film 1111 is provided, for example, selectively at a position in the semiconductor layer 1100S opposed to the pixel isolation portion 1117. The insulating film 1111 is provided to cover the light shielding film 1117A. The insulating film 1111 is for example made of silicon oxide.

The wiring layer 1100T between the semiconductor layer 1100S and the second substrate 1200 has, in this order from the side of the semiconductor layer 1100S, an interlayer insulating film 1119, pad portions 1120 and 1121, a passivation film 1122, an interlayer insulating film 1123 and a junction film 1124. The horizontal portion TGb of the transfer gate TG is for example provided in the wiring layer 1100T. The interlayer insulating film 1119 is provided over the entire surface of the semiconductor layer 1100S and is in contact with the semiconductor layer 1100S. The interlayer insulating film 1119 is for example made of silicon oxide. The configuration of the wiring layer 1100T is not limited to the above and can be any configuration having a wiring and an insulating film.

The pad portions 1120 and 1121 are provided in selective areas on the interlayer insulating film 1119. The pad portions 1120 are configured to connect the floating diffusions FD of the pixels 541A, 541B, 541C, and 541D to each other.

The pad portion 1121 is configured to connect a plurality of VSS contact regions 1118 to each other. For example, the VSS contact regions 1118 in pixels 541C and 541D of one shared pixel unit 539 adjacent to each other in the V direction and the VSS contact regions 1118 in pixels 541A and 541B of another shared pixel unit 539 are electrically connected by the pad portion 1121. The pad portion 1121 is for example provided across the pixel isolation portion 1117 to overlap at least a part of each of these four VSS contact regions 1118.

Specifically, the pad portion 1121 is formed in a region overlapping at least a part of each of the plurality of VSS contact regions 1118 and at least a part of the pixel isolation portion 1117 formed between those plurality of VSS contact regions 1118 in a direction perpendicular to the surface of the semiconductor layer 1100S. In the interlayer insulating film 1119, connection vias 1121C are provided to electrically connect the pad portions 1121 and the VSS contact regions 1118. The connection vias 1121C are provided in each of pixels 541A, 541B, 541C, and 541D. For example, a part of the pad portion 1121 is embedded in the connection via 1121C, so that the pad portion 1121 and the VSS contact region 1118 are electrically connected.

The presence of the pad portion 1120 allows the wirings for connecting between each floating diffusion FD and the pixel circuit 1210 to be reduced for the entire chip. Similarly, the presence of the pad portion 1121 allows the wirings to supply potential to each of the VSS contact regions 1118 to be reduced on the entire chip. In this way, the overall area of the chip can be reduced, electrical interference between wirings in miniaturized pixels can be suppressed, and/or the cost reduction can be achieved by reducing the number of components.

The pad portions 1120 and 1121 can be provided at desired locations on the first substrate 1100 and the second substrate 1200. Specifically, the pad portions 1120 and 1121 can be provided in either the wiring layer 1100T or the insulating region 1212 of the semiconductor layer 1200S. When provided in the wiring layer 1100T, the pad portions 1120 and 1121 can be directly contacted with the semiconductor layer 1100S. Specifically, the pad portions 1120 and 1121 may be configured to be directly connected to at least a part of each of the floating diffusions FD and/or the VSS contact regions 1118. Also, connection vias 1120C and 1121C may be provided from each of the floating diffusions FD and/or the VSS contact regions 1118 that are to be connected to the pad portions 1120 and 1121, and the pad portions 1120 and 1121 may be provided at desired locations in the fixed charge film 1112 of the wiring layer 1100T and the semiconductor layer 1200S.

In particular, when the pad portions 1120 and 1121 are provided in the wiring layer 1100T, the wirings connected to the floating diffusions FD and/or the VSS contact regions 1118 in the insulating region 1212 of the semiconductor layer 1200S can be reduced. As a result, the area of the insulating region 1212 for forming through wirings to connect between the floating diffusion FD and the pixel circuit 1210 can be reduced in the second substrate 1200 that forms the pixel circuit 1210. Therefore, the area of the second substrate 1200 for forming the pixel circuit 1210 can be increased. A sufficient area can be secured for the pixel circuit 1210, so that the pixel transistor can be formed in a larger area, which can contribute to improved image quality for example through noise reduction.

In particular, when the FTI structure is used for the pixel isolation portion 1117, the floating diffusion FD and/or VSS contact region 1118 are preferably provided in each pixel 541, so that the presence of the pad portions 1120 and 1121 allows the wirings for connecting the first substrate 1100 and the second substrate 1200 to be significantly reduced.

For example, the pad portions 1120 and 1121 are made of polysilicon (Poly Si). More specifically, an impurity doped polysilicon. The pad portions 1120 and 1121 are preferably made of a highly heat-resistant conductive material such as polysilicon, tungsten (W), titanium (Ti), and titanium nitride (TiN).

The passivation film 1122 is provided over the entire surface of the semiconductor layer 1100S for example to cover the pad portions 1120 and 1121. The passivation film 1122 is made of for example a silicon nitride (SiN) film. The interlayer insulating film 1123 covers the pad portions 1120 and 1121 with the passivation film 1122 therebetween. The interlayer insulating film 1123 is provided for example over the entire surface of the semiconductor layer 1100S. The interlayer insulating film 1123 is made of for example a silicon oxide (SiO) film. The junction film 1124 is provided on the junction surface between the first substrate 1100 (specifically, the wiring layer 1100T) and the second substrate 1200. More specifically, the junction film 1124 is in contact with the second substrate 1200. The junction film 1124 is provided over the entire main surface of the first substrate 1100. The junction film 1124 is for example made of a silicon nitride film.

The light receiving lens 1401 is opposed to the semiconductor layer 1100S for example with the fixed charge film 1112 and the insulating film 1111 therebetween. The light receiving lens 1401 is provided at a position opposed to the photodiode PD of each of the pixels 541A, 541B, 541C, 541D, for example.

The second substrate 1200 has a semiconductor layer 1200S and a wiring layer 1200T in this order from the side of the first substrate 1100. The semiconductor layer 1200S is made of a silicon substrate. In the semiconductor layer 1200S, a well region 1211 is provided in the thickness-wise direction. The well region 1211 is for example a p-type semiconductor region. The second substrate 1200 is provided with a pixel circuit 1210 which is arranged for each shared pixel unit 539. The pixel circuit 1210 is provided for example on the front surface side of the semiconductor layer 1200S (the side of the wiring layer 1200T). In the light detection device 1D, the second substrate 1200 is attached to the first substrate 1100 so that the back surface side (the side of the semiconductor layer 1200S) of the second substrate 1200 is opposed to the front surface side (the side of the wiring layer 1100T) of the first substrate 1100. In other words, the second substrate 1200 is bonded to the first substrate 1100 face to back.

### Function and Effect According to Fifth Embodiment

As described above, according to the fifth embodiment, the same function and effect as those according to the first embodiment can be provided using the three-layer stacked pixel arrangement.

### Other Embodiments

While the present technique has been described above in the form of the first to fifth embodiments and the modification example of the second embodiment, the descriptions and the drawings that form a part of the disclosure should not be construed as limiting the present technology. When the gist of the disclosed technical content according to the first to fifth embodiments is understood, various alternative embodiments, examples, and operation technology that fall within the range of the present technology will be apparent to a person skilled in the art. In addition, the configurations in the first to fifth embodiments and the modification of the second embodiment can be combined as appropriate within a range where there is no contradiction. For example, configurations disclosed in a plurality of different embodiments may be combined, or configurations disclosed in a plurality of different modifications of the same embodiment may be combined.

### Example of Application to Electronic Device

The light detection devices described above can be used in various electronic devices, for example, an imaging device such as a digital still camera and a digital video camera, a cellular phone having an imaging function, or any other device having an imaging function.

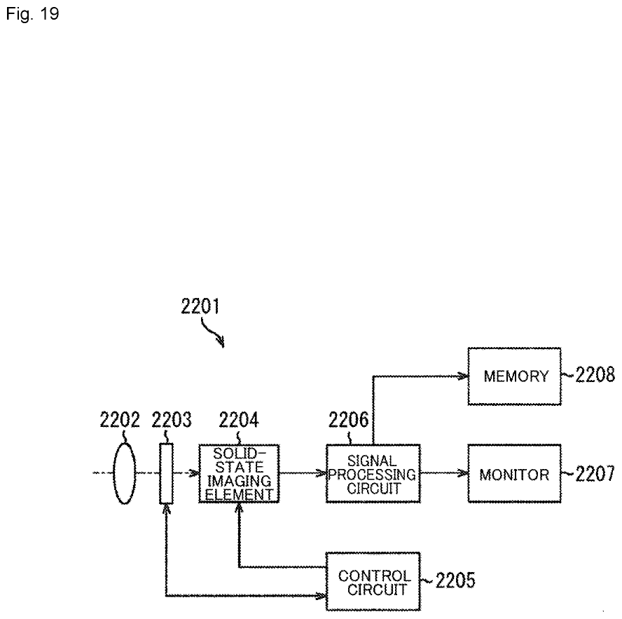

FIG. 19 is a block diagram showing a configuration example of an imaging device as an electronic device to which the present technology is applied.

The imaging device 2201 shown in FIG. 19 includes an optical system 2202, a shutter device 2203, a solid-state imaging element 2204 as a light detection device, a control circuit 2205, a signal processing circuit 2206, a monitor 2207, and two memories 2208, and the imaging device can capture still-images and moving images.

The optical system 2202 includes one or more lenses, and guides light (incident light) from an object to the solid-state imaging element 2204, and forms an image on the light receiving surface of the solid-state imaging element 2204.

The shutter device 2203 is arranged between the optical system 2202 and the solid-state imaging element 2204, and controls a light emission period and a light-blocking period for the solid-state imaging element 2204 according to the control of the control circuit 2205.

The solid-state imaging element 2204 includes a package including the above-described solid-state imaging element. The solid-state imaging element 2204 accumulates signal charge for a certain period of time according to the light imaged on the light-receiving surface via the optical system 2202 and the shutter device 2203. The signal charge accumulated in the solid-state imaging element 2204 is transferred in response to a drive signal (timing signal) supplied from the control circuit 2205.

The control circuit 2205 outputs a drive signal that controls the transfer operation of the solid-state imaging element 2204 and the shutter operation of the shutter device 2203, and drives the solid-state imaging element 2204 and the shutter device 2203.

The signal processing circuit 2206 performs various kinds of signal processing on the signal charge output from the solid-state imaging element 2204. An image (image data) obtained by the signal processing performed by the signal processing circuit 2206 is supplied to the monitor 2207 for display or supplied to the memory 2208 for storage (recording).

In the imaging device 2201 having the configuration, the light detection device 1A, 1B, 1C, or 1D can be used instead of the above solid-state imaging element 2204.

### Example of Application to Endoscopic Surgery System

The technique according to the present disclosure (the present technique) can be applied to various products. For example, the technique according to the present disclosure may be applied to an endoscopic surgery system.

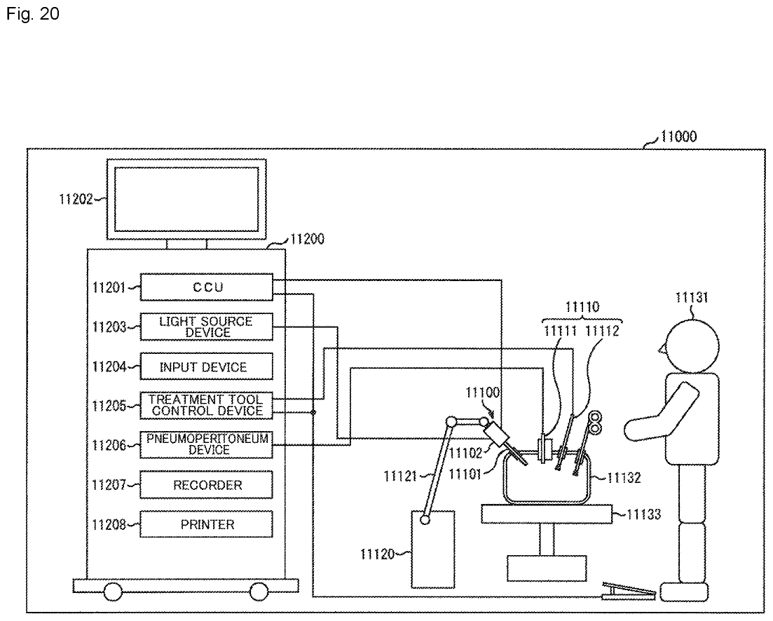

FIG. 20 is a diagram illustrating an example of a schematic configuration of an endoscope surgery system to which the technology according to the present disclosure (the present technology) is applied.

FIG. 20 shows a state where an operator (doctor) 11131 is using an endoscopic surgery system 11000 to perform a surgical operation on a patient 11132 on a patient bed 11133. As illustrated, the endoscopic surgery system 11000 is constituted of an endoscope 11100, another surgical instrument 11110 such as a pneumoperitoneum tube 11111 or an energized treatment tool 11112, a support arm apparatus 11120 that supports the endoscope 11100, and a cart 11200 mounted with various apparatuses for endoscopic surgery.

The endoscope 11100 includes a lens barrel 11101 of which a region having a predetermined length from a tip thereof is inserted into a body cavity of the patient 11132, and a camera head 11102 connected to a base end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image is generated. The image signal is transmitted to a camera control unit (CCU) 11201 as RAW data.

The CCU 11201 is constituted by a central processing unit (CPU), a graphics processing unit (GPU), and the like and comprehensively controls the operation of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 is constituted of, for example, a light source such as an LED (Light Emitting Diode) and supplies the endoscope 11100 with irradiation light when photographing a surgical site or the like.

An input device 11204 is an input interface for the endoscopic surgery system 11000. The user can input various types of information or instructions to the endoscopic surgery system 11000 via the input device 11204. For example, the user inputs an instruction to change imaging conditions (a type of radiation light, a magnification, a focal length, or the like) of the endoscope 11100.

A treatment tool control device 11205 controls driving of the energized treatment tool 11112 for cauterization or incision of a tissue, sealing of blood vessel, or the like. A pneumoperitoneum device 11206 sends a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies the endoscope 11100 with the radiation light for imaging the surgical site can be configured of, for example, an LED, a laser light source, or a white light source configured of a combination thereof. When a white light source is formed by a combination of RGB laser light sources, it is possible to control an output intensity and an output timing of each color (each wavelength) with high accuracy, and thus the light source device 11203 can adjust white balance of the captured image. Further, in this case, laser light from each of the respective RGB laser light sources is radiated to the observation target in a time division manner, and driving of the imaging element of the camera head 11102 is controlled in synchronization with radiation timing such that images corresponding to respective RGB can be captured in a time division manner. According to this method, it is possible to obtain a color image without providing a color filter in the imaging element.

Further, driving of the light source device 11203 may be controlled so that an intensity of output light is changed at predetermined time intervals. The driving of the image sensor of the camera head 11102 is controlled in synchronization with a timing of changing the intensity of the light, and images are acquired in a time division manner and combined, such that an image having a high dynamic range without so-called blackout and whiteout can be generated.

In addition, the light source device 11203 may have a configuration in which light in a predetermined wavelength band corresponding to special light observation can be supplied. In the special light observation, for example, by emitting light in a band narrower than that of radiation light (that is, white light) during normal observation using wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source device 11203 may have a configuration in which narrow band light and/or excitation light corresponding to such special light observation can be supplied.

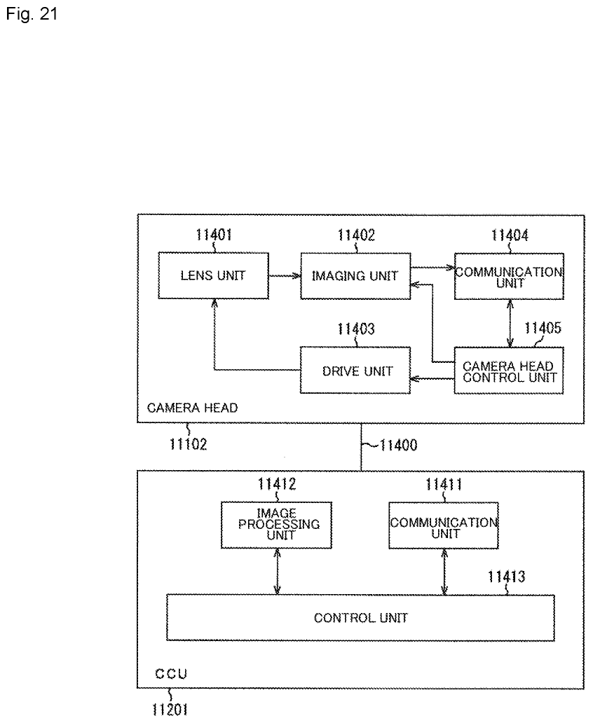

FIG. 21 is a block diagram showing an example of functional configurations of the camera head 11102 and the CCU 11201 shown in FIG. 20.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light taken from a tip of the lens barrel 11101 is guided to the camera head 11102 and is incident on the lens unit 11401. The lens unit 11401 is configured in combination of a plurality of lenses including a zoom lens and a focus lens.

The imaging unit 11402 is constituted by an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. When 3D display is performed, the operator 11131 can ascertain the depth of biological tissues in the surgical site more accurately. When the imaging unit 11402 is configured in a multi-plate type, a plurality of systems of lens units 11401 may be provided in correspondence to the image sensors.

The imaging unit 11402 need not necessarily be provided in the camera head 11102. For example, the imaging unit 11402 may be provided immediately after the objective lens inside the lens barrel 11101.

The drive unit 11403 is configured by an actuator and the zoom lens and the focus lens of the lens unit 11401 are moved by a predetermined distance along an optical axis under the control of the camera head control unit 11405. Accordingly, the magnification and focus of the image captured by the imaging unit 11402 can be adjusted appropriately.

The communication unit 11404 is configured using a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the camera head control unit 11405 with the control signal. The control signal includes, for example, information regarding imaging conditions such as information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, a so-called auto focus (AF) function, and a so-called auto white balance (AWB) function are provided in the endoscope 11100.

The camera head control unit 11405 controls driving of the camera head 11102 on the basis of a control signal from the CCU 11201 received via the communication unit 11404.

The communication unit 11411 is constituted of a communication device that transmits and receives various kinds of information to and from the camera head 11102. The communication unit 11411 receives an image signal transmitted via the transmission cable 11400 from the camera head 11102.

Further, the communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various kinds of control on imaging of a surgical site by the endoscope 11100, display of a captured image obtained through imaging of a surgical site, or the like. For example, the control unit 11413 generates a control signal for controlling driving of the camera head 11102.

In addition, the control unit 11413 causes the display device 11202 to display a captured image showing a surgical site or the like based on an image signal subjected to the image processing by the image processing unit 11412. In doing so, the control unit 11413 may recognize various objects in the captured image using various image recognition techniques. For example, the control unit 11413 can recognize a surgical instrument such as forceps, a specific biological site, bleeding, mist or the like at the time of use of the energized treatment tool 11112, or the like by detecting a shape, a color, or the like of an edge of an object included in the captured image. When the display device 11202 is caused to display a captured image, the control unit 11413 may superimpose various kinds of surgery support information on an image of the surgical site for display using a recognition result of the captured image. By displaying the surgery support information in a superimposed manner and presenting it to the operator 11131, a burden on the operator 11131 can be reduced, and the operator 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of the endoscopic surgery system to which the technique according to the present disclosure can be applied has been described above. The technique according to the present disclosure may be applied to, for example, the endoscope 11100, the imaging unit 11402 of the camera head 11102, the image processing unit 11412 of the CCU 11201, and the like among the components described above. Specifically, the light detection device 1A of FIG. 1 can be applied to the imaging unit 10402.

Here, although the endoscopic operation system has been described as an example, the technology according to the present disclosure may be applied to other, for example, a microscopic operation system.

### Example of Application to Mobile Object

The technology of the present disclosure (the present technology) can be applied to various products. For example, the technique according to the present disclosure may be realized as a device mounted on any type of moving body such as an automobile, an electric automobile, a hybrid electric automobile, a motorcycle, a bicycle, a personal mobility device, an airplane, a drone, a ship, a robot, or the like.

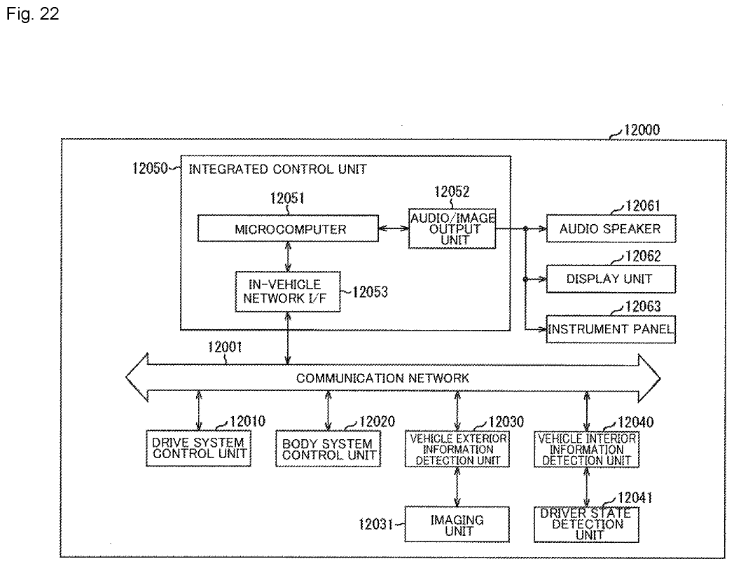

FIG. 22 is a block diagram illustrating a schematic configuration example of a vehicle control system, which is an example of a moving body control system to which the technique according to the present disclosure can be applied. The vehicle control system 12000 includes a plurality of electronic control units connected thereto via a communication network 12001. In the example illustrated in FIG. 22, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, an audio/image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio/image output unit 12052 transmits an output signal of at least one of sound and an image to an output device capable of visually or audibly notifying a passenger or the outside of the vehicle of information. In the example of FIG. 22, an audio speaker 12061, a display unit 12062, and an instrument panel 12063 are illustrated as examples of the output device. The display unit 12062 may include at least one of an on-board display and a head-up display, for example.

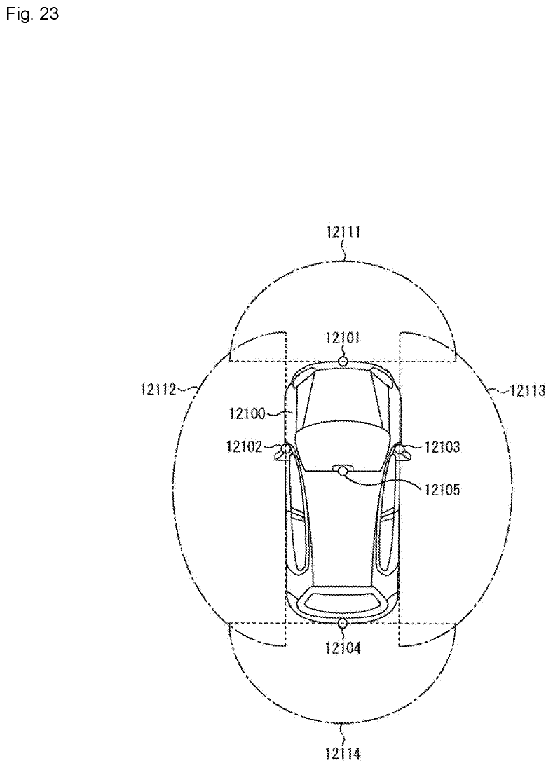

FIG. 23 is a diagram showing an example of an installation position of the imaging unit 12031.

In FIG. 23, a vehicle 12100 includes imaging units 12101, 12102, 12103, 12104, and 12105 as the imaging unit 12031.

The imaging units 12101, 12102, 12103, 12104, and 12105 are provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of the front of the vehicle 12100. The imaging units 12102 and 12103 provided on the side-view mirrors mainly acquire images of a lateral side of the vehicle 12100. The imaging unit 12104 provided on the rear bumper or the back door mainly acquires images of the rear of the vehicle 12100. Front view images acquired by the imaging units 12101 and 12105 are mainly used for detection of preceding vehicles, pedestrians, obstacles, traffic lights, traffic signs, lanes, and the like.

FIG. 23 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (for example, 0 km/h or higher) in the substantially same direction as the vehicle 12100, as a vehicle ahead by acquiring a distance to each three-dimensional object in the imaging ranges 12111 to 12114 and a temporal change of the distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the audio/image output unit 12052 controls the display unit 12062 so that a square contour line for emphasis is superimposed and displayed with the recognized pedestrian. In addition, the audio/image output unit 12052 may control the display unit 12062 so that an icon indicating a pedestrian or the like is displayed at a desired position.

An example of the vehicle control system to which the technology according to the present disclosure can be applied has been described above. The technique according to the present disclosure is applicable to the imaging unit 12031 or the like among the configurations described above. Specifically, the technique can be applied to the light detection device 1A in FIG. 1.

The present disclosure can also be configured as follows.

(1)

A light detection device comprising: a first substrate portion having a pixel configured to photoelectrically convert incident light;
a second substrate portion stacked on a surface of the first substrate portion opposite to a surface on which the light is incident and having a readout circuit configured to output a pixel signal based on charge output from the pixel to a signal line; and
a through via configured to connect the first substrate portion and the second substrate portion,
the pixel having a floating diffusion configured to temporarily retain charge generated by photoelectric conversion,
the readout circuit having
a first pixel transistor connected to the floating diffusion through the through via, and
a second pixel transistor connected to the first pixel transistor and the signal line, the through via being provided, in plan view, between a contact portion provided at a gate electrode of the first pixel transistor and a contact portion provided at a gate electrode of the second pixel transistor in a region of the pixel and in a position shifted in a second direction orthogonal to a first direction in which the contact portion of the first pixel transistor and the contact portion of the second pixel transistor are provided.
   (2)

The light detection device according to (1), wherein the through via is provided in a position shifted in the second direction orthogonal to a wiring path configured to connect the contact portion of the first pixel transistor and the contact portion of the second pixel transistor.

(3)

The light detection device according to (2), wherein current is passed from the first pixel transistor to the second pixel transistor in the wiring path.

(4)

The light detection device according to (1), further comprising a plurality of the pixels and a plurality of the readout circuits, wherein at least some of the plurality of pixels form a shared pixel, the first pixel transistor and the second pixel transistor are shared between a plurality of pixels that form the shared pixel.

(5)

The light detection device according to (4), wherein the through via is provided, in plan view, between the contact portion of the first pixel transistor provided in a first readout circuit and the contact portion of the second pixel transistor provided in a second readout circuit among the plurality of readout circuits and in a position shifted in the second direction orthogonal to the first direction in which the contact portion of the first pixel transistor and the contact portion of the second pixel transistor are provided.

(6)

The light detection device according to (1), wherein in plan view, if the first direction corresponds to an x-coordinate and the second direction corresponds to a y-coordinate, the position coordinates of the contact portion of the first pixel transistor are (x1, y1), the position coordinates of the second pixel transistor are (x2, y2), and the position coordinates of the through-via are (x3, y3), x3 is a value between x1 and x2, and y3 is a value different from y1 and y2.

(7)

The light detection device according to (1), wherein in plan view, if the first direction corresponds to a y-coordinate, the second direction corresponds to an x-coordinate, the position coordinates of the contact portion of the first pixel transistor are (x1, y1), the position coordinates of the second pixel transistor are (x2, y2), and the position coordinates of the through-via are (x3, y3), x3 is a value different from x1 and x2, and y3 is a value between y1 and y2.

(8)

The light detection device according to (1), wherein the first pixel transistor is an amplification transistor having a gate electrode connected to the floating diffusion to generate, as the pixel signal, a signal for voltage corresponding to a charge amount retained by the floating diffusion.

(9)

The light detection device according to (1), wherein the second pixel transistor is a selection transistor configured to control timing for outputting the pixel signal.

(10)

The light detection device according to (1), wherein the first pixel transistor and the second pixel transistor have a planar shape.

(11)

The light detection device according to (1), wherein the first pixel transistor and the second pixel transistor have a fin shape having a three-channel structure.

(12)

The light detection device according to (1), wherein the first pixel transistor and the second pixel transistor have an L shape with two channel directions.

(13)

The light detection device according to (1), wherein the first pixel transistor and the second pixel transistor have a GAA (Gate All Around) shape having a four-channel structure.

(14)

An electronic device comprising a light detection device, the light detection device comprising: a first substrate portion having a pixel configured to photoelectrically convert incident light;
a second substrate portion stacked on a surface of the first substrate portion opposite to a surface on which the light is incident and having a readout circuit configured to output a pixel signal based on charge output from the pixel to a signal line; and
a through via configured to connect the first substrate portion and the second substrate portion,
the pixel having a floating diffusion configured to temporarily retain charge generated by photoelectric conversion,
the readout circuit having
a first pixel transistor connected to the floating diffusion through the through via, and
a second pixel transistor connected to the first pixel transistor and the signal line, the through via being provided, in plan view, between a contact portion provided at a gate electrode of the first pixel transistor and a contact portion provided at a gate electrode of the second pixel transistor in a region of the pixel and in a position shifted in a second direction orthogonal to a first direction in which the contact portion of the first pixel transistor and the contact portion of the second pixel transistor are provided.

### REFERENCE SIGNS LIST

1A, 1B, 1C, 1D Light detection device
2 Semiconductor chip
2A Pixel region
2B Peripheral region
3, 3-1, 3-2, 3-3, 3-4 Pixel
4 Vertical drive circuit
5 Column signal processing circuit
6 Horizontal drive circuit
7 Output circuit
8 Control circuit
10 Pixel drive line
11 Vertical signal line (VSL)
12 Horizontal signal line
13 Logic circuit
14 Bonding pad
15 Readout circuit
21 Semiconductor substrate
22 Well region (semiconductor region)
23 Isolation region
24 Gate insulating film
25, 204 Gate electrode
26, 27 Semiconductor region
29 Photoelectric conversion unit
30 Insulating layer
31, 33, 51, 53 Insulating film
32, 64 Wiring layer
32a, 64a, 64b, 64e, 64f, 64g, 64g1, 64g2, 64g3 Wiring
52a, 52b, 52d Base
54a, 54b, 54b1, 54b2, 54b3, 54c, 54d, 54d1, 54d2, 54d3 Contact portion
55a First semiconductor portion
55b Second semiconductor portion
55c Third semiconductor portion
56a First active region
56b Second active region
56c, 56d Third active region
57 Semiconductor layer
58,154 Gate insulating film
59a, 59b, 59c, 59d, 155, 204 Gate electrode
60 Insulating film
62, 62A, 62B Through-via
63f, 63g Contact electrode
65 Conductive path
71 Planarization film
72 Color filter
73 Microlens
150 MOS transistor
151, 152 Readout circuit
151a Front surface
153 Semiconductor region
153a Upper surface
153b, 153c Side surface
156 Sidewall
157 Source region
201 Low concentration N-type region
202 First high concentration N-type region
202a Opposing region
202b Bottom region
203 Second high concentration N-type region
205 First insulating film
206 Second insulating film
207 Third insulating film
510A Input unit
510B Output unit
511 Input terminal
512 Input circuit portion
513 Input amplitude change unit
514 Input data change circuit portion
515 Output data change circuit portion
516 Output amplitude change unit
517 Output circuit portion
518 Output terminal
520 Row drive unit
530 Timing control unit
539 Shared pixel unit
540 Pixel array portion
540B Peripheral portion
541, 541A, 541B, 541C, 541D Pixel
542 Row drive signal line
543 Vertical signal line
544 Power supply line
550 Column signal processing unit
560 Image signal processing unit
1100 First substrate
1100S, 1200S, 1300S Semiconductor layer
1100T, 1200T, 1300T Wiring layer
1111, 1117B Insulating film
1112 Fixed charge film
1113 First pinning region
1114 n-type semiconductor region
1115 p-well layer
1116 Second pinning region
1117 Pixel isolation portion
1117A Light shielding film
1118 VSS contact region
1119, 1123 Interlayer insulating film
1120, 1121 Pad portion
1120C, 1121C Connection via
1120E, 1121E Through electrode
1122 Passivation film
1124 Junction film
1200 Second substrate
1201, 1202, 1301, 1302 Contact portion
1201R, 1202R, 1301R, 1302R Contact region
1210 Pixel circuit
1211 Well region
1212 Insulating region
1300 Third substrate
1401 Light receiving lens
1551 First portion
1552 Second portion
1553 Third portion
2201 Imaging device
2202 Optical system
2203 Shutter device
2204 Solid-state imaging element
2205 Control circuit
2206 Signal processing circuit
2207 Monitor
2208 Memory
10402 Imaging unit
11000 Endoscopic surgery system
11100 Endoscope
11101 Lens barrel
11102 Camera head
11110 Surgical instrument
11111 Pneumoperitoneum tube
11112 Energized treatment tool
11120 Support arm apparatus
11131 Operator (doctor)
11132 Patient
11133 Patient bed
11200 Cart
11201 Camera control unit (CCU)
11202 Display device
11203 Light source device
11204 Input device
11205 Treatment tool control device
11206 Pneumoperitoneum device
11207 Recorder
11208 Printer
11400 Transmission cable
11401 Lens unit
11402, 12031 Imaging unit
11403 Driving unit
11404, 11411 Communication unit
11405 Camera head control unit
11412 Image processing unit
11413 Control unit
12000 Vehicle control system
12001 Communication network
12010 Drive system control unit
12020 Body system control unit
12030 Vehicle exterior information detecting unit
12040 Vehicle interior information detecting unit
12041 Driver state detecting unit
12050 Integrated control unit
12051 Microcomputer
12052 Audio/image output unit
12061 Audio speaker
12062 Display unit
12063 Instrument panel
12100 Vehicle
12101, 12102, 12103, 12104, 12105 Imaging unit
12111, 12112, 12113, 12114 Imaging range

1. A light detection device comprising: a first substrate portion having a pixel configured to photoelectrically convert incident light;
a second substrate portion stacked on a surface of the first substrate portion opposite to a surface on which the light is incident and having a readout circuit configured to output a pixel signal based on charge output from the pixel to a signal line; and
a through via configured to connect the first substrate portion and the second substrate portion,
the pixel having a floating diffusion configured to temporarily retain charge generated by photoelectric conversion,
the readout circuit having
a first pixel transistor connected to the floating diffusion through the through via, and
a second pixel transistor connected to the first pixel transistor and the signal line, the through via being provided, in plan view, between a contact portion provided at a gate electrode of the first pixel transistor and a contact portion provided at a gate electrode of the second pixel transistor in a region of the pixel and in a position shifted in a second direction orthogonal to a first direction in which the contact portion of the first pixel transistor and the contact portion of the second pixel transistor are provided.

2. The light detection device according to claim 1, wherein the through via is provided in a position shifted in the second direction orthogonal to a wiring path configured to connect the contact portion of the first pixel transistor and the contact portion of the second pixel transistor.

3. The light detection device according to claim 2, wherein current is passed from the first pixel transistor to the second pixel transistor in the wiring path.

4. The light detection device according to claim 1, further comprising a plurality of the pixels and a plurality of the readout circuits, wherein
at least some of the plurality of pixels form a shared pixel, the first pixel transistor and the second pixel transistor are shared between a plurality of pixels that form the shared pixel.

5. The light detection device according to claim 4, wherein the through via is provided, in plan view, between the contact portion of the first pixel transistor provided in a first readout circuit and the contact portion of the second pixel transistor provided in a second readout circuit among the plurality of readout circuits and in a position shifted in the second direction orthogonal to the first direction in which the contact portion of the first pixel transistor and the contact portion of the second pixel transistor are provided.

6. The light detection device according to claim 1, wherein in plan view, if the first direction corresponds to an x-coordinate and the second direction corresponds to a y-coordinate, the position coordinates of the contact portion of the first pixel transistor are (x1, y1), the position coordinates of the second pixel transistor are (x2, y2), and the position coordinates of the through-via are (x3, y3), x3 is a value between x1 and x2, and y3 is a value different from y1 and y2.

7. The light detection device according to claim 1, wherein in plan view, if the first direction corresponds to a y-coordinate, the second direction corresponds to an x-coordinate, the position coordinates of the contact portion of the first pixel transistor are (x1, y1), the position coordinates of the second pixel transistor are (x2, y2), and the position coordinates of the through-via are (x3, y3), x3 is a value different from x1 and x2, and y3 is a value between y1 and y2.

8. The light detection device according to claim 1, wherein the first pixel transistor is an amplification transistor having a gate electrode connected to the floating diffusion to generate, as the pixel signal, a signal for voltage corresponding to a charge amount retained by the floating diffusion.

9. The light detection device according to claim 1, wherein the second pixel transistor is a selection transistor configured to control timing for outputting the pixel signal.

10. The light detection device according to claim 1, wherein the first pixel transistor and the second pixel transistor have a planar shape.

11. The light detection device according to claim 1, wherein the first pixel transistor and the second pixel transistor have a fin shape having a three-channel structure.

12. The light detection device according to claim 1, wherein the first pixel transistor and the second pixel transistor have an L shape with two channel directions.

13. The light detection device according to claim 1, wherein the first pixel transistor and the second pixel transistor have a GAA (Gate All Around) shape having a four-channel structure.

14. An electronic device comprising a light detection device, the light detection device comprising: a first substrate portion having a pixel configured to photoelectrically convert incident light;
a second substrate portion stacked on a surface of the first substrate portion opposite to a surface on which the light is incident and having a readout circuit configured to output a pixel signal based on charge output from the pixel to a signal line; and
a through via configured to connect the first substrate portion and the second substrate portion,
the pixel having a floating diffusion configured to temporarily retain charge generated by photoelectric conversion,
the readout circuit having
a first pixel transistor connected to the floating diffusion through the through via, and
a second pixel transistor connected to the first pixel transistor and the signal line, the through via being provided, in plan view, between a contact portion provided at a gate electrode of the first pixel transistor and a contact portion provided at a gate electrode of the second pixel transistor in a region of the pixel and in a position shifted in a second direction orthogonal to a first direction in which the contact portion of the first pixel transistor and the contact portion of the second pixel transistor are provided.
